(19) United States
(12) Patent Application Publication
(10) Pub. No.: US 2026/0070158 A1
(43) Pub. Date: Mar. 12, 2026

(54) System to Reduce Induced Subsurface Damage in Separation of Semiconductor Workpieces

(71) Applicant: Wolfspeed, Inc., Durham, NC (US)

(72) Inventor: Simon Bubel, Carrboro, NC (US)

(21) Appl. No.: 18/830,879

(22) Filed: Sep. 11, 2024

(51) Int. Cl. B23K 26/40; B23K 26/53; B23K 101/40; B23K 103/00; C30B 29/36; H01L 21/268; H01L 21/78; H01L 29/16

(52) U.S. Cl. CPC B23K 26/40; B23K 26/53; C30B 29/36; H10D 62/8325; H10P 34/42; H10P 54/00; B23K 2101/40; B23K 2103/50

(57) ABSTRACT

Systems and methods to process a semiconductor workpiece are provided. One example method includes providing a semiconductor workpiece having a subsurface damage region. The method includes performing a treatment process on the subsurface damage region. The treatment process includes providing a treatment emission of radiation from a radiation source to the subsurface damage region of the workpiece at a non-perpendicular angle relative to the subsurface damage region.

### FIELD

The present disclosure relates generally to semiconductor workpieces and semiconductor device fabrication, and more particularly to processing of semiconductor workpieces, such as silicon carbide semiconductor boules or wafers.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

Semiconductor devices may be fabricated from wide bandgap semiconductor materials, such as silicon carbide and/or Group III-nitride based semiconductor materials. The fabrication process for power semiconductor devices may require processing of wide bandgap semiconductor wafers, such as silicon carbide semiconductor wafers.

### SUMMARY

Aspects and advantages of embodiments of the present disclosure will be set forth in part in the following description, or can be learned from the description, or can be learned through practice of the embodiments.

One example aspect of the present disclosure is directed toward a method to process a semiconductor workpiece. The method includes providing a semiconductor workpiece having a subsurface damage region. The method includes performing a treatment process on the subsurface damage region. The treatment process includes providing a treatment emission of radiation from a radiation source to the subsurface damage region of the workpiece at a non-perpendicular angle relative to the subsurface damage region.

Another example aspect of the present disclosure is directed to a method to process a semiconductor workpiece. The method includes providing a semiconductor workpiece. The method includes inducing a subsurface damage region with a damage-inducing emission of radiation from a first radiation source. The method includes performing a treatment process on the subsurface damage region with a treatment emission of radiation from a second radiation source. The damage-inducing emission of radiation from the first radiation source differs from the treatment emission of radiation from the second radiation source.

Another example aspect of the present disclosure is directed toward a system to process a semiconductor workpiece. The system includes a first radiation source configured to provide a damage-inducing emission, wherein the damage-inducing emission is configured to induce a subsurface damage region in the semiconductor workpiece. The system includes a second radiation source configured to provide a treatment emission, wherein the treatment emission is configured to perform a treatment process on the subsurface damage region of the semiconductor workpiece. The system includes at least one translation stage operable to impart relative motion between the subsurface damage region of the semiconductor workpiece and the radiation source.

Another example aspect of the present disclosure is directed toward a semiconductor wafer. The semiconductor wafer includes a first major surface and a second major surface. The semiconductor wafer including the first major surface has a post-processed surface roughness in a range of about 0.5 nanometers to about 180 nanometers and the second major surface of the semiconductor wafer has surface roughness of about 10 microns to about 100 microns or greater. The semiconductor wafer includes a fracture strength in a range of about 17.5 Newtons or greater.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 is a first perspective view crystal plane diagram showing the coordinate system for a hexagonal crystal such as 4H-silicon carbide.

FIG. 2 is a second perspective view crystal plane diagram for a hexagonal crystal, illustrating a vicinal plane that is non-parallel to the c-plane.

FIG. 3A is a perspective view wafer orientation diagram showing orientation of a vicinal wafer relative to the c-plane.

FIG. 3B is a simplified cross-sectional view of the vicinal wafer of FIG. 4A superimposed over a portion of a boule.

FIG. 3C is a perspective view of a wafer orientation diagram showing orientation of an on-axis wafer relative to the c-plane.

FIG. 3D is simplified cross-sectional view of the wafer of FIG. 3C superimposed over a portion of a boule.

FIG. 4 is a top plan view of an example silicon carbide wafer.

FIG. 5A is a side elevation schematic view of an on-axis boule of crystalline material.

FIG. 5B is a side elevation schematic view of the boule of FIG. 5A being rotated by 4 degrees, with a superimposed pattern for cutting end portions of the boule.

FIG. 5C is a side elevation schematic view of a boule following removal of end portions to provide end faces that are non-perpendicular to the c-direction.

FIG. 5D is a side elevation schematic view of an off-axis grown boule of crystalline material.

FIG. 5E is a side elevation schematic view of an off-axis grown boule having end faces that are non-perpendicular to the c-direction.

FIG. 6 depicts an overview of an example method according to examples of the present disclosure.

FIG. 7 is a cross-sectional schematic view of a crystalline material substrate including a first subsurface laser damage pattern centered at a first depth.

FIG. 8 is a cross-sectional schematic view of the substrate of FIG. 7 following formation of a second subsurface laser damage pattern centered at a second depth and registered with the first subsurface laser damage pattern, with an overlapping vertical extent of the first and second damage patterns.

FIG. 9 depicts a cross-sectional representation of a semiconductor workpiece that has been subjected to a subsurface damage inducing process according to examples of the present disclosure.

FIG. 10 depicts a cross-sectional representation of a semiconductor workpiece that has been subjected to a removal process according to examples of the present disclosure.

FIG. 11 depicts emission of one or more laser sources at a non-perpendicular incidence angle relative to a subsurface damage region in a semiconductor workpiece according to examples of the present disclosure.

FIG. 12 depicts an overview of an example method according to examples of the present disclosure.

FIG. 13 depicts example laser-based subsurface damage region processing of a semiconductor workpiece according to examples of the present disclosure.

FIG. 14 depicts an example laser processing system according to examples of the present disclosure.

FIG. 15 depicts an overview of example control of a radiation source based at least in part on sensor data from one or more sensors according to examples of the present disclosure.

FIG. 16 depicts an array of lasers implementing a laser-based subsurface treatment operation on a semiconductor workpiece according to examples of the present disclosure.

FIGS. 17-18 depict an example testing apparatus and method for determining fracture strength of a semiconductor workpiece according to examples of the present disclosure.

FIG. 19 depicts a semiconductor wafer according to examples of the present disclosure.

FIGS. 20-26 depict example scan patterns for a laser-based processing operation according to examples of the present disclosure.

FIG. 27 depicts a flowchart according to an example method of the present disclosure.

FIG. 28 depicts a flowchart according to an example method of the present disclosure.

FIG. 29 depicts a flowchart according to an example method of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Power semiconductor devices are often fabricated from wide bandgap semiconductor materials, such as silicon carbide or group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that the technology according to example embodiments of the present disclosure may be used with any semiconductor material, such as other wide bandgap semiconductor materials, without deviating from the scope of the present disclosure. Example wide bandgap semiconductor materials include silicon carbide and the group III-nitrides.

Power semiconductor devices may be fabricated using epitaxial layers formed on a semiconductor workpiece, such as a silicon carbide semiconductor wafer. Aspects of the present disclosure are discussed with reference to a semiconductor workpiece that is a semiconductor wafer that includes silicon carbide (“silicon carbide semiconductor wafer”) for purposes of illustration and discussion. Those of ordinary skill in the art, using the disclosures provided herein, will understand that aspects of the present disclosure can be used with other semiconductor workpieces, such as other wide bandgap semiconductor workpieces. Other semiconductor workpieces may include carrier substrates, ingots, boules, polycrystalline substrates, monocrystalline substrates, bulk materials having a thickness of greater than 1 millimeter, such as greater than about 5 millimeters, such as greater than about 10 millimeters, such as greater than about 20 millimeters, such as greater than about 50 millimeters, such as greater than about 100 millimeters, such as greater than about 200 millimeters, etc.

In some examples, the semiconductor workpiece includes silicon carbide crystalline material. The silicon carbide crystalline material may have a 4H crystal structure, 6H crystal structure, or other crystal structure. The semiconductor workpiece can be an on-axis workpiece (e.g., end face parallel to the (0001) plane) or an off-axis workpiece (e.g., end face non-parallel to the (0001) plane).

Aspects of the present disclosure may make reference to a surface of the semiconductor workpiece. In some examples, the surface of the workpiece may be, for instance, a silicon face of the workpiece. In some examples, the surface of the workpiece may be, for instance, a carbon face of the workpiece.

In some examples, a semiconductor wafer may be a solid semiconductor workpiece upon which semiconductor device fabrication may be implemented. A semiconductor wafer may be a homogenous material, such as silicon carbide, and may provide mechanical support for the formation and/or carrying of additional semiconductor layers (e.g., epitaxial layers), metallization layers, and other layers to form one or more semiconductor devices. In some examples, a semiconductor wafer may have a thickness in a range of about 0.5 microns to about 1000 microns, or greater.

A semiconductor wafer may be characterized by a plurality of surfaces. For example, a semiconductor wafer may have a “first major surface” and a “second major surface. ” The first major surface may be generally opposite the second major surface. The first and second major surfaces may be generally parallel to one another. A semiconductor wafer may also have a “side surface” corresponding to a surface extending between the two major surfaces. For example, the side surface may extend between the first major surface and the second major surface.

Power semiconductor device fabrication processes may include surface processing operations that are performed on the silicon carbide semiconductor wafer to prepare one or more surfaces of the silicon carbide semiconductor wafer for later processing steps, such as surface implantation, formation of epitaxial layers, metallization, etc. Example surface processing operations may include grinding operations, lapping operations, and polishing operations. Methods for surface processing of semiconductor wafers in semiconductor manufacturing may include grinding, lapping, and/or polishing the rough surfaces until a sufficient smoothness and/or thickness is achieved.

Grinding is a material removal process that is used to remove material from the semiconductor wafer. Grinding may be used to reduce a thickness of a semiconductor wafer. Grinding typically involves exposing the semiconductor wafer to an abrasive containing surface, such as grinding teeth on a grind wheel. Grinding may remove material of the semiconductor wafer through engagement with the abrasive surface.

Lapping is a precision finishing process that uses a loose abrasive in slurry form. The slurry typically includes coarser particles (e.g., largest dimension of the particles being greater than about 100 microns) to remove material from the semiconductor wafer. Lapping typically does not include engaging the semiconductor wafer with an abrasive-containing surface on the lapping tool (e.g., a wheel or disc having an abrasive-containing surface). Instead, the semiconductor wafer typically comes into contact with a lapping plate or a tile usually made of metal. Lapping typically provides better planarization of the semiconductor wafer relative to grinding.

Polishing is a process to remove imperfections and create a very smooth surface with a low surface roughness. Polishing may be performed using a slurry and a polishing pad. The slurry typically includes finer particles relative to lapping, but coarser particles relative to chemical mechanical planarization (CMP). Polishing typically provides better planarization of the semiconductor wafer relative to grinding.

CMP is a type of fine or ultrafine polishing, typically used to produce a smoother surface ready, for instance, for epitaxial growth of layers on the semiconductor wafer. CMP may be performed chemically and/or mechanically to remove imperfections and to create a very smooth and flat surface with low surface roughness. CMP typically involves changing the material of the semiconductor through a chemical process (e.g., oxidation) and removing the new material from the semiconductor wafer through abrasive contact with a slurry and/or other abrasive surface or polishing pad (e.g., oxide removal). In CMP, the abrasive elements in the slurry typically remove the product of the chemical process and do not remove the bulk material of the semiconductor wafer, often leaving very low subsurface damage.

Aspects of the present disclosure refer to and/or claim a “surface roughness” of a surface. As used herein, unless otherwise specifically noted, the surface roughness is measured as “areal average roughness” Sa. When the present disclosure or claims refer to a surface having a surface roughness being within a range of values, a surface has a surface roughness in the range of values if any 1 millimeter by 1 millimeter area on the surface includes a surface roughness Sa within the specified range of values or if any 1 millimeter by 1 millimeter area on the surface includes a surface roughness Sz (maximum height) within the specified range of values. As an example, a surface has a surface roughness in a range of 0.5 nm to 180 nm if any 1 millimeter×1 millimeter area on the surface has a surface roughness Sa in the range of 0.5 nanometers to 180 nanometers or if any 1 millimeter×1 millimeter area on the surface has a surface roughness Sz in the range of 0.5 nanometers to 180 nanometers. For the sake of clarity, it is not required that the entire surface have the surface roughness in the specified range of values. Only a single 1 millimeter×1 millimeter area on the surface is required to have a surface roughness in the specified range of values (e.g., either Sa or Sz) for the surface to be considered to have a surface roughness in the specified range of values.

Methods for fabricating semiconductor wafers from semiconductor material boules may incur significant material losses and consumable tool losses and costs due to the structural properties of crystalline boules and current methods of separating or fracturing substrates from a boule. Methods for fabricating power semiconductor devices include forming a crystalline material boule, such as a silicon carbide boule, and separating portions of the boule to form substrates, such as silicon carbide semiconductor wafers. In some instances, boules may be formed to include doped regions with dopants within the crystalline material boule.

Methods for forming semiconductor wafers from boules may include, for instance, cutting thin layers (e.g., wafers) from the boule using wire saws. Another example removal process for forming semiconductor wafers from boules may include a laser-based removal process. Laser-based removal processes may include providing subsurface laser damage patterns to a boule to form weakened areas in the boule. Portions may then be separated from the boule along the weakened areas to produce semiconductor wafers. Separation processes may include, for example, ultrasonic fracturing, mechanical force fracturing, or other fracturing methods.

The separating (e.g., fracturing and/or sawing) process may produce a rough and uneven surface on both the boule and the crystalline material substrates (e.g., semiconductor wafers) separated from the boule. Semiconductor devices and device manufacturing may require smooth surfaces on a semiconductor workpiece. Accordingly, in some cases, before continuing with further separations of the boule or further manufacturing with the semiconductor workpiece, the rough surface(s) may need to be subjected to surface processing operations. For instance, in some examples, the surface of the boule may be smoothed to allow for the formation of subsequent laser damage regions in the boule. Otherwise, a rough surface on the boule may lead to undesirable reflection/refraction of one or more laser(s) used during formation of the subsurface laser damage regions for removal of subsequent semiconductor wafers. Methods for surface processing of boules and substrates (e.g., semiconductor wafers) in semiconductor manufacturing may include grinding, lapping, and/or polishing the rough surfaces until a sufficient smoothness is achieved.

Some surface processing operations (e.g., grinding, lapping, polishing, etc.) may include planarizing rough or deeply grooved silicon carbide surfaces. Planar surface processing operations may expose a surface of the semiconductor wafer to a generally planar tool surface (e.g., grinding wheel, grind disc, polishing pad) for removing and/or smoothing material. The planar tool surface may remove material from “peaks” in the rough surface before removing material from deep trenches, valleys, or grooves in the rough surface. In this way, a planar surface processing operation may remove material from the semiconductor wafer and reduce surface roughness. Example planar surface processing operations include using a polishing pad, grind disc, or grind wheel.

Non-planar surface processing operations do not use a planar tool surface. For instance, non-planar surface processing operations may remove material from peaks and from valleys in the surface indiscriminately (e.g., at a nearly uniform rate). As a result, non-planar surface processing operations may replicate the surface topography of a semiconductor workpiece as material is removed from the semiconductor workpiece instead of smoothing the surface topography of the semiconductor workpiece. Non-planar surface processing operations may effectively remove material from the semiconductor wafer but may be unable to effectively reduce surface roughness. Example non-planar surface processing operations may include, for instance, laser-based surface processing operations, such as laser ablation on a surface of the semiconductor wafer. Other non-planar surface processing operations may include, for instance, electrochemical operations, reactive ion etching (RIE) based surface processing operations, plasma-based surface processing operations, sputtering-based surface processing operations, and/or a wet etch-based surface processing operations.

Grinding methods may incur substantial time, material, and consumable tool loss and cost due to the structural properties of the crystalline materials used in semiconductor devices and smoothness requirements of semiconductor devices. Materials used in wide bandgap semiconductor devices, such as, for example, silicon carbide, have extreme rigidity and strength requiring expensive tools (e.g., with diamond abrasive elements) that are rapidly consumed. The grinding process also results in material losses from grinding away potentially usable material to provide a sufficiently smooth surface for semiconductor device manufacturing.

Laser-based surface processing operations may provide reduced consumable tool loss and reduced cost compared to grinding methods. However, as indicated above, laser-based surface processing operations, in some examples, may be non-planar surface processing operations. Most notably, non-planar laser-based surface processing operations emitting a laser in a generally perpendicular direction relative to the surface of the semiconductor workpiece may ablate or remove materials from peaks and valleys of a surface of a workpiece indiscriminately. Rather than creating a uniform smooth surface on the workpiece, a non-planar laser ablation method may recreate the rough surface at a reduced height (e.g., reduced thickness) of the workpiece.

Systems and methods for separating a first portion of a semiconductor workpiece from a second portion of a semiconductor workpiece may rely on an induced damage region that is generally parallel to the upper surface of the semiconductor workpiece, or the implementation of a subsurface interface below the upper surface of a semiconductor workpiece at a targeted depth. The induced subsurface damage region may allow for removal or separation techniques to separate a first portion of the workpiece from a second portion of the workpiece along the subsurface damage region. Such systems and methods may rely on multiple passes of an emission of radiation or implantation of species, such as the emission of a laser, to induce subsurface damage at a target depth below the upper surface of a semiconductor workpiece. The emission of radiation that induces the subsurface damage region may be performed such that the emission of radiation enters the upper surface of the semiconductor workpiece at an angle that is largely perpendicular to the direction the subsurface damage region formed by the emission of radiation is oriented. The angle of the emission of radiation that induces the subsurface damage region leads to a plurality of cracks that are oriented in an undesirable direction, that is to say, the subsurface damage region has an undesired vertical component in addition to a horizontal component. The undesired vertical component of the cracks in the induced subsurface damage region may be worsened when multiple passes of the emission of radiation are performed, which may be necessary to ensure removal processes are able to separate the first portion and the second portion of a semiconductor workpiece efficiently. The repetition of passes of the emission of radiation further increases the severity of the undesired vertical component of the cracks, and when a separation or removal technique is performed, there may be significant material losses associated with the undesired vertical component to the propagation of the cracks.

Additionally, such systems and methods for separating a first portion of a semiconductor workpiece from a second portion of a semiconductor workpiece may rely on ion (or other species) implantation to induce a subsurface damage region. The ion implanted subsurface damage region may be susceptible to similar undesired vertical crack propagation during a separation or removal process as outlined above.

Further, when a separation or removal technique is performed to separate a first portion of the semiconductor workpiece from a second portion of a semiconductor workpiece along the induced subsurface damage region, the newly created surfaces on both the first and the second portion of the semiconductor workpiece may have increased surface roughness due to the presence of the vertical component of the cracks that may propagate during a separation process.

In addition to increasing the surface roughness of the newly created surfaces of a first portion and/or a second portion of a semiconductor workpiece, the plurality of cracks with a vertical component may form peaks or trenches on the newly created surfaces of the first portion and/or the second portion of the semiconductor workpiece, which may act as stress concentrators that reduce the fracture strength of the first portion and/or the second portion of a semiconductor workpiece after a removal or separation process has been performed. Because of this reduced fracture strength, the first portion and/or the second portion of the semiconductor workpiece may have an elevated breakage rate during subsequent processing operations (e.g., surface processing operations such as grinding, lapping, polishing, CMP, ECMP, etc.), which increases cost and reduces yield and capacity.

Accordingly, aspects of the present disclosure are directed to methods for processing a semiconductor workpiece, such as a silicon carbide semiconductor boule or wafer. One example aspect of the present disclosure is directed to a method to process a semiconductor workpiece, such as a semiconductor boule or wafer. The method includes providing a semiconductor workpiece having a subsurface damage region. The method includes performing a treatment process on the subsurface damage region, where the treatment process includes an emission of radiation from a radiation source to the subsurface damage region.

Another example aspect of the present disclosure is directed to a method to process a semiconductor workpiece, such as a semiconductor boule or wafer. The method includes providing a semiconductor workpiece. The method includes inducing a subsurface damage region with a damage-inducing emission of radiation from a first radiation source. The method includes performing a treatment process on the subsurface damage region with a treatment emission of radiation from a second radiation source, where the damage-inducing emission of radiation from the first radiation source differs from the treatment emission of radiation from the second radiation source. As used herein, an emission of radiation that differs from another emission of radiation (e.g., a damage-inducing emission of radiation from a first radiation source that differs from a treatment emission of radiation from a second radiation source) may differ in source type (e.g., a first radiation source that is laser-based and a second radiation source that is an incandescent lamp, by non-limiting example), or in source parameters of the same source type (e.g., incidence angle, optical path, power, frequency, pulse width/length, etc.).

Another example aspect of the present disclosure is directed to a method to process a semiconductor workpiece, such as a semiconductor boule or wafer. The method includes providing a semiconductor workpiece that includes an upper and a lower surface. The method includes inducing a subsurface damage region between the upper surface and the lower surface of the semiconductor workpiece with a damage-inducing emission of radiation from a first radiation source. The method includes performing a treatment process on the subsurface damage region with a treatment emission of radiation from a second radiation source, where at least one of the damage-inducing emissions of radiation from the first source or the treatment emissions of radiation from the second source are provided to the semiconductor workpiece at a non-perpendicular angle relative to the upper surface of the workpiece. The method includes separating the semiconductor workpiece along the subsurface damage region using a removal process.

Another example aspect of the present disclosure is related to a semiconductor wafer. The semiconductor wafer includes a first major surface and a second major surface. The first surface of the semiconductor wafer includes a surface roughness in a range of about 0.5 nanometers to about 180 nanometers, while the second major surface of the semiconductor wafer has a surface roughness of about 10 microns to about 100 microns or greater. The semiconductor wafer includes an increase in fracture strength in a range of about 17.5 Newtons or greater relative to an example semiconductor wafer produced by induced damage separation processes.

In some examples, the semiconductor workpiece is a silicon carbide boule. In some examples, the semiconductor workpiece is a semiconductor wafer, such as a thick silicon carbide wafer (such as wafers having a thickness of greater than about 500 microns, such as greater than about 750 microns, such as greater than about 1000 microns). In some examples, the semiconductor workpiece may undergo additional fabrication operations prior to the method of the present disclosure, such as partial or complete substrate or device formation on a major surface of the workpiece, such as a backside thinning process (e.g., prior to backside metallization). In some examples, the method for processing a semiconductor workpiece may include providing a semiconductor workpiece having a subsurface damage region and performing a treatment process on the subsurface damage region. In some examples, the subsurface damage region is a laser-based damage region in the workpiece. In some examples, the subsurface damage region is an ion implantation damage region in the workpiece. The treatment process may include providing an emission of radiation from a radiation source to the subsurface damage region of the workpiece at a non-perpendicular angle relative to the subsurface damage region. In some examples, the non-perpendicular angle is about 75°or less. In some examples, the non-perpendicular angle is about 30°or less. In some examples, the non-perpendicular angle is about 15°or less.

In some examples, the radiation source may be one or more laser sources that provide the emission of the radiation to the subsurface damage region of a semiconductor workpiece. In some examples, the laser treatment process may be conducted by one or more laser sources in the infrared, visible, and/or the ultraviolet range of the electromagnetic spectrum. In some examples, the one or more laser sources may be operated in continuous or pulsed modes. In some examples, the one or more radiation sources may be operable with an average power from about 1 to about 500 W, such as about 1 to about 100 W, such as about 5 W to about 30 KW, such as about 200 W to about 300 W. In some examples, the one or more radiation sources may be operable with continuous power supplied or with a frequency of about 0.1 kHz to about 20 MHz. The one or more radiation sources may include coherent radiation sources, such as electric gas discharge lasers (e.g., a gas discharge radiation source where a fraction of emitted electromagnetic radiation is amplified), metal vapor lasers (e.g., a copper vapor lasing medium), yttrium aluminum garnet (YAG) lasers including doped YAG lasers (e.g., Nd:YAG or Yb:YAG), fiber lasers (e.g., ytterbium doped glass) or rod lasers (e.g., chromium doped chrysoberyl), diode lasers (e.g., GaN, GaAs, and/or diode lasers containing InP). The one or more radiation sources may be operated in a manner that allows nonlinear frequency conversion (e.g., frequency doubling or tripling) to meet absorption and/or optical requirements of the workpiece. The one or more radiation sources may additionally include optical means to modify the angle of incidence of the emission of radiation relative to the surface of the workpiece, or otherwise modify the emission of radiation, which may produce tuned irradiance profiles of the emission along a propagation distance.

In some examples, the radiation source may be one or more gas discharge sources that provide the emission of the radiation to the subsurface damage region of a semiconductor workpiece. The gas discharge treatment process may include exposure to electromagnetic radiation generated by low or high pressure ionization of xenon, carbon dioxide, mercury, or sodium in a gaseous form.

In some examples, the radiation source may be one or more incandescent radiation sources that provide the emission of the radiation to the subsurface damage region of a semiconductor workpiece. The incandescent radiation treatment process may include a filament-based radiation source and/or a halogen cycle (e.g., a halogen tungsten lamp). The incandescent radiation source may be operable in a range of about 5 watts to about 30,000 watts, such as about 5 watts to about 500 watts, or about 0.5 kilowatts to about 20 kilowatts. The incandescent radiation treatment process may include optical elements to tune optical energy (e.g., optical elements that steer, shape, or focus radiation such as lenses, mirrors, collimators, etc.) from the incandescent radiation source.

In some examples, the radiation source may be one or more electroluminescence emitters that provide the emission of the radiation to the subsurface damage region of a semiconductor workpiece. The electroluminescence emitter treatment process may include one or more light emitting diodes (LEDs) operable in a range of about 5 watts to about 30,000 watts, such as about 5 watts to about 500 watts, or about 0.5 kilowatts to about 30 kilowatts. The electroluminescence radiation treatment process may include optical elements to tune optical energy (e.g., optical elements that steer, shape, or focus radiation such as lenses, mirrors, collimators, etc.) from the incandescent radiation source.

In some examples, the radiation source may be one or more electronic or magnetic oscillators that provide the emission of the radiation to the subsurface damage region of a semiconductor workpiece. The electronic or magnetic treatment process may include a high-vacuum tube operable to generate and/or amplify electromagnetic radiation resulting from interactions of electrons within the tube. The electromagnetic radiation may encompass radio wavelengths, terahertz wavelengths, or microwave wavelengths, such as electromagnetic radiation that ranges from about 0.1 millimeters to about 1 meter.

In some examples, the radiation source may be one or more free electron resonators that provide the emission of the radiation to the subsurface damage region of a semiconductor workpiece. The free electron resonator treatment process may include treatment with coherent radiation resulting from electron beam propagation through a magnetic field.

In some examples, the radiation source may be one or more x-ray emitters that provide the emission of the radiation to the subsurface damage region of a semiconductor workpiece. The x-ray emitter treatment process may include the generation of electromagnetic radiation (e.g., x-rays) resulting from the bombardment of high-speed electrons with a target material. The resulting electromagnetic radiation may be a result of electrons bound with the target material falling into lower energy states.

In some examples, the radiation source may be one or more bremsstrahlung emitters that provide the emission of the radiation to the subsurface damage region of a semiconductor workpiece. The bremsstrahlung treatment process may include the generation of electromagnetic radiation (e.g., x-rays) resulting from an abrupt velocity change due to a collision or other scattering event of an electron interacting with an atomic nucleus.

In some examples, the method comprises separating a semiconductor wafer from the semiconductor workpiece after the treatment process using a removal process. In some examples, the treatment process reduces a surface roughness Sz of at least one major surface of the semiconductor wafer after separation compared to a wafer that does not undergo a treatment process according to aspects of the present disclosure. In some examples, at least one major surface of the semiconductor wafer has a surface roughness of about 10 microns to about 100 microns or greater. In some examples, at least one major surface of the semiconductor wafer has a surface roughness in a range of about 0.5 nanometer to about 180 nanometers.

In some examples, providing the emission of the radiation to the subsurface damage region of the workpiece at a non-perpendicular angle relative to the subsurface damage region increases a fracture strength of the semiconductor workpiece (e.g., a semiconductor wafer resulting from a removal process of a semiconductor workpiece from a boule or other structure). That is, in some examples the semiconductor workpiece may be a first portion obtained after a removal process on a workpiece with an induced subsurface damage region. In some examples, the workpiece may be a portion of the workpiece above or below the induced subsurface damage region prior to a removal technique. In some examples, the treatment process provides the fracture strength of the semiconductor wafer in a range of about 17.5 Newtons or greater. In some examples, the treatment process provides a fracture strength in a range of about 25 Newtons to about 75 Newtons. In some examples, the fracture strength is determined by placing the semiconductor wafer on two support structures and providing a force on the semiconductor wafer at a location halfway between the two support structures, wherein the fracture strength corresponds to the greatest force provided to the semiconductor wafer without breaking.

In some examples, the method may include performing a surface processing operation on the workpiece, wherein implementing the treatment process is performed prior to performing the surface processing operation.

In some examples, the method may include obtaining data indicative of a workpiece property, wherein the method may include adjusting the non-perpendicular angle, optical path, frequency modulation, power modulation, and/or focus area of the emission of the radiation from the radiation source based on the data indicative of the workpiece property. In some examples, the method may include adjusting a scan angle of the emission of the radiation source relative to one or more features of the subsurface damage region of the workpiece.

In some examples, the method involves imparting relative motion between the radiation source and the workpiece. In some examples, imparting relative motion between the radiation source and the workpiece may include adjusting the non-perpendicular angle of the emission of the radiation source while imparting relative motion.

In some examples, the method may include providing a semiconductor workpiece. The method may include inducing a subsurface damage region with a damage-inducing emission of radiation from a first radiation source. The method may include performing a treatment process on the subsurface damage region with a treatment emission of radiation from a second radiation source, where the damage-inducing emission of radiation from the first radiation source differs from the treatment emission of radiation from the second radiation source. In some examples, the first radiation source may include one or more laser sources that provide the damage-inducing emission of radiation to a subsurface region of a semiconductor workpiece.

In some examples, the method may include providing a semiconductor workpiece, the semiconductor workpiece including an upper surface and a lower surface and inducing a subsurface damage region between the upper surface and the lower surface of the semiconductor workpiece with a damage-inducing emission of radiation from a first radiation source. The method may include performing a treatment process on the subsurface damage region with a treatment emission of radiation from a second radiation source wherein at least one of the damage-inducing emission of radiation from the first source or the treatment emission of radiation from the second source is provided to the semiconductor workpiece at a non-perpendicular angle relative to the upper surface of the workpiece. In some examples, the damage-inducing emission of radiation from the first radiation source may differ from the treatment emission of radiation from the second radiation source, for example, the second radiation source may include a differing pulse duration (e.g., a shorter pulse duration), differing power density (e.g. less irradiance per unit area), differing pulse energy (e.g., higher maximum optical energy over the duration of a laser pulse), or differing wavelengths (e.g., a higher energy wavelength).

Aspects of the present disclosure relate to a system for processing a semiconductor workpiece. The system may include a first radiation source configured to provide a damage-inducing emission, wherein the damage-inducing emission is configured to induce a subsurface damage region in the semiconductor workpiece. The system may include a second radiation source configured to provide a treatment emission, wherein the treatment emission is configured to perform a treatment process on the subsurface damage region of the semiconductor workpiece at a non-perpendicular angle relative to the subsurface damage region, or at a plurality of incidence angles, such as simultaneously over a range of angles that may or may not include a perpendicular incidence angle. The system may include at least one translation stage operable to impart relative motion between the subsurface damage region of the semiconductor workpiece and the radiation source.

In some examples, the system may include a controller, wherein the controller is configured to adjust one or more of the radiation source, the translation stage, or one or more optics to adjust the non-perpendicular angle of the emission of the radiation source relative to the subsurface damage region of the semiconductor workpiece. In some examples, the controller is configured to adjust the non-perpendicular angle as a function of position of the subsurface damage region of the workpiece.

In some examples, the system may include a sensor configured to obtain sensor data indicative of a workpiece property and/or a property of the subsurface damage region. The system may include a controller that is configured to adjust the non-perpendicular angle based at least in part on the sensor data. In some examples, the sensor is an optical sensor, a surface measurement laser, or an image capture device. In some examples, the controller is configured to adjust one or more radiation parameters based at least in part on the sensor data. In some examples, the one or more radiation parameters include one or more of power, frequency modulation, pulse frequency, wavelength, pulse duration, focusing depth, pulse energy, scan pattern, scan angle, translation speed, or focus area.

Aspects of the present disclosure relate to a semiconductor wafer. In some examples, the semiconductor wafer may include a first major surface and a second major surface, wherein the first major surface has a surface roughness in a range of about 0.5 nanometers to about 180 nanometers and the second major surface of the semiconductor wafer has a damage region fractured surface roughness in a range of about 10 microns to about 100 microns. In some examples, the semiconductor wafer has an increase in a fracture strength in a range of about 17.5 Newtons or greater relative to a semiconductor wafer produced by induced damage separation processes. In some examples, the surface roughness Sz of the semiconductor wafer is reduced due to an emission of radiation from a radiation source to a semiconductor workpiece during processing operations. In some examples, the semiconductor wafer is a silicon carbide semiconductor wafer.

Aspects of the present disclosure provide technical effects and benefits. For instance, reducing the vertical component of cracks formed in the subsurface damage region may reduce material losses of a semiconductor workpiece associated with separation processes. Reducing the propagation of cracks in the vertical direction may allow for a semiconductor workpiece to undergo a larger number of subsurface damage region inducing processes, subsurface damage region treatment processes, and subsequently, more removal processes which may increase yield from a bulk material (e.g., a boule). Additionally, aspects of the present disclosure provide example methods by which the quality of a semiconductor workpiece, such as a semiconductor wafer, may be improved. For example, surface roughness and fracture strength are important qualities when making considerations for further fabrication performed on a semiconductor workpiece. Aspects of the present disclosure provide methods which reduce the surface roughness of newly created surfaces on a first portion and a second portion of a semiconductor workpiece that has undergone a separation process and increases the fracture strength by decreasing the severity of stress concentration areas. This may increase yield and capacity.

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based semiconductor structures, such as silicon carbide-based MOSFETs. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

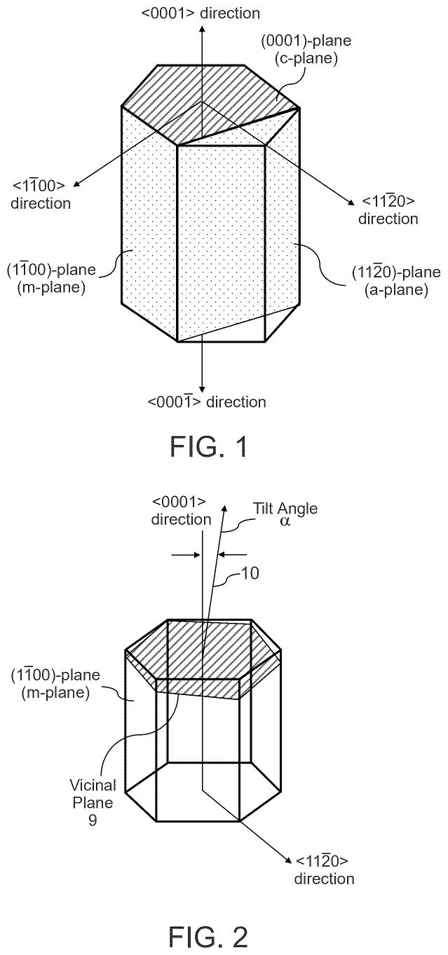

FIG. 1 is a first perspective view crystal plane diagram showing the coordinate system for a hexagonal crystal such as 4H-silicon carbide (“SiC”), in which the c-plane (0001) is perpendicular to both the m-plane (11̅00) and the a-plane (112̅0). The c-plane is perpendicular to the <0001> direction. The m-plane (11̅00) is perpendicular to the <11̅00> direction. The a-plane (112̅0) is perpendicular to the <112̅0> direction. The <0001̅> direction is opposite the <0001> direction

FIG. 2 is a second perspective view crystal plane diagram for a hexagonal crystal, illustrating a vicinal plane 9 that is non-parallel to the c-plane, wherein a vector 10 (which is normal to the vicinal plane 9) is tilted away from the <0001> direction by a tilt angle α, with the tilt angle α being inclined (slightly) toward the <112̅0> direction.

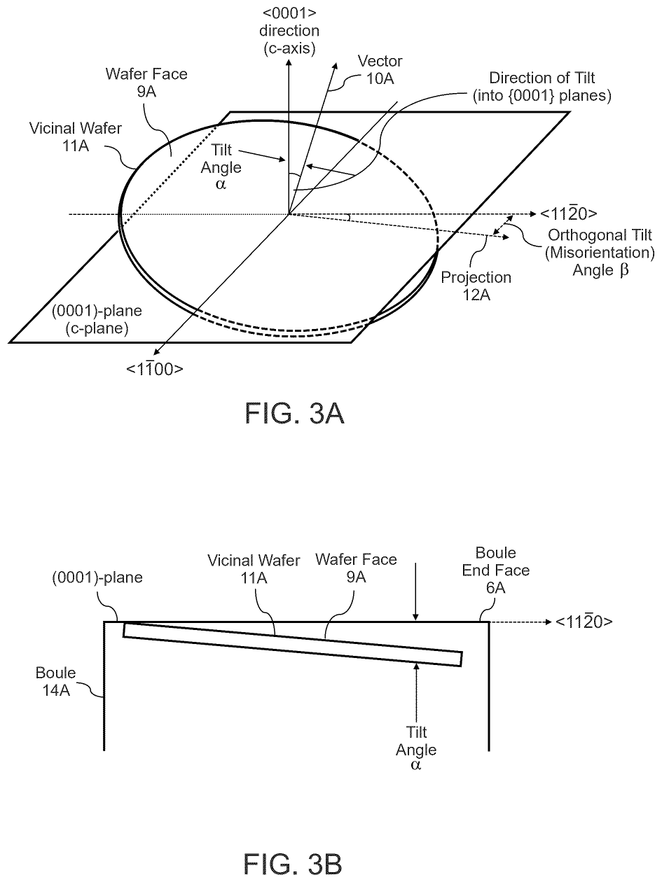

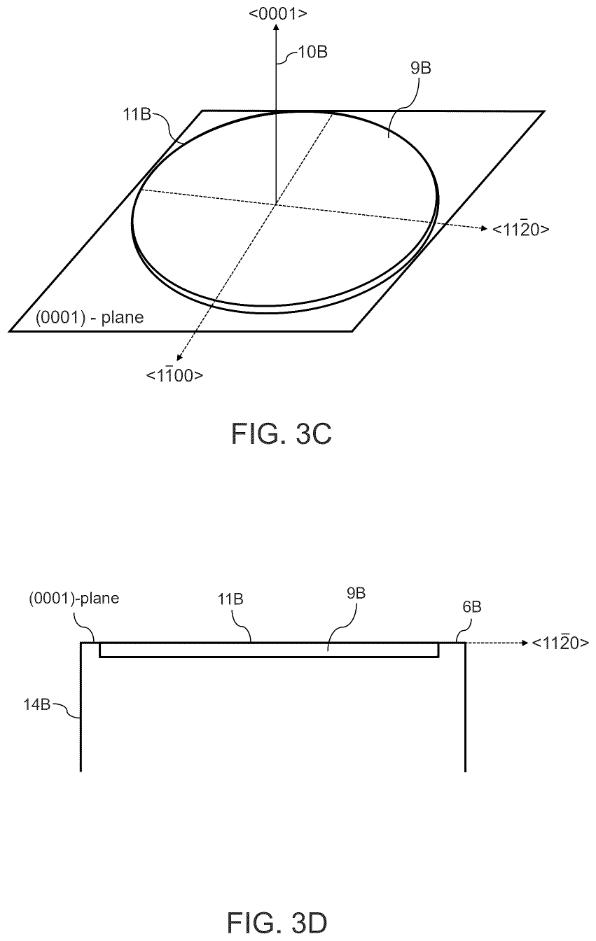

FIG. 3A is a perspective view of a wafer orientation diagram showing orientation of a vicinal wafer 11A relative to the c-plane (0001), in which a vector 10A (which is normal to the wafer face 9A) is tilted away from the <0001> direction by a tilt angle α. An orthogonal tilt (or misorientation angle) β may span between the <112̅0> direction and the projection of vector 10A onto the c-plane.

FIG. 3B is a simplified cross-sectional view of the vicinal wafer 11A superimposed over a portion of a boule 14A (e.g., an on-axis boule having an end face 6A parallel to the (0001) plane) from which the vicinal wafer 11A was defined. FIG. 3B shows that the wafer face 9A of the vicinal wafer 11A is misaligned relative to the (0001) plane by a tilt angle α. FIG. 3C is a perspective view of a wafer orientation diagram showing orientation of an on-axis wafer relative to the c-plane. FIG. 3D is simplified cross-sectional view of the wafer of FIG. 3C superimposed over a portion of a boule.

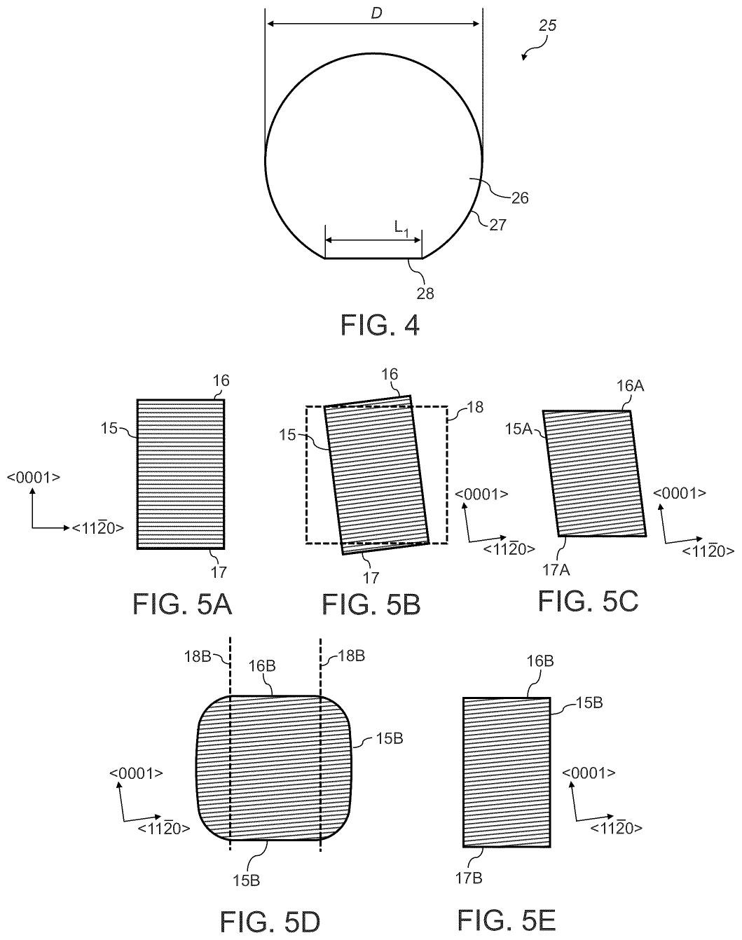

FIG. 4 is a top plan view of an example silicon carbide semiconductor wafer 25 including an upper face 26. The silicon carbide semiconductor wafer 25 may include a surface that is misaligned with (e.g., off-axis at an oblique angle relative to) the c-plane. The silicon carbide semiconductor wafer 25 may be laterally bounded by a generally round edge 27 (having a diameter D) including a primary flat 28 (having a length L₁) that is perpendicular, for instance, to the (112̅0) plane. In some instances, the wafer 25 may include a notch instead of a flat. FIG. 5A is a side elevation schematic view of an on-axis boule of crystalline material.

Methods disclosed herein may be applied to substrates of various crystalline materials, of both single crystal and polycrystalline varieties. In certain embodiments, methods disclosed herein may utilize cubic, hexagonal, and other crystal structures, and may be directed to crystalline materials having on-axis and off-axis crystallographic orientations. In certain embodiments, methods disclosed herein may be applied to semiconductor materials and/or wide bandgap materials. Example materials include, but are not limited to, silicon, gallium arsenide, and diamond.

In certain embodiments, such methods may utilize single crystal semiconductor materials having hexagonal crystal structure, such as 4H-SiC, 6H-SiC, or Group III nitride materials (e.g., GaN, AlN, InN, InGaN, AlGaN, or AlInGaN). Various illustrative embodiments described hereinafter mention SiC generally or 4H-SiC specifically, but it is to be appreciated that any suitable crystalline material may be used. Among the various SiC polytypes, the 4H-SiC polytype is particularly attractive for power electronic devices due to its high thermal conductivity, wide bandgap, and isotropic electron mobility. Bulk silicon carbide may be grown on-axis (i.e., with no intentional angular deviation from the c-plane thereof, suitable for forming undoped or semi-insulating material) or off-axis (typically departing from a grown axis such as the c-axis by a non-zero angle, typically in a range of from 0.5 to 10 degrees (or a subrange thereof such as 2 to 6 degrees or another subrange), as may be suitable for forming n-doped or highly conductive material).

Certain embodiments herein may use substrates of doped or undoped silicon carbide, such as silicon carbide boules, which may be grown by physical vapor transport (PVT) or other conventional boule fabrication methods. If doped SiC is used, such doping may render the SiC n-type or semi-insulating in character. In certain embodiments, an n-type silicon carbide boule is intentionally doped with nitrogen. In certain embodiments, an n-type silicon carbide boule includes resistivity values within a range of 0.015 to 0.028 Ohm-centimeters. In certain embodiments, a silicon carbide boule may have resistivity values that vary with vertical position, such that different substrate portions (e.g., wafers) have different resistivity values, which may be due to variation in bulk doping levels during boule growth.

FIGS. 5A and 5C schematically illustrate on-axis and off-axis crystalline substrates in the form of boules that may be utilized with methods disclosed herein. FIG. 5A is a side elevation schematic view of an on-axis boule 15 of crystalline material having first and second end faces 16, 17 that are perpendicular to the c-direction (i.e., <0001> direction for a hexagonal crystal structure material such as 4H-SiC). FIG. 5B is a side elevation schematic view of the boule 15 of FIG. 5A being rotated by four degrees, with a superimposed pattern 18 (shown in dashed lines) for cutting and removing end portions of the boule 15 proximate to the end faces 16, 17. FIG. 5C is a side elevation schematic view of an off-axis boule 15A formed from the boule 15 of FIG. 5B, following removal of end portions to provide new end faces 16A, 17A that are non-perpendicular to the c-direction. Aspects of the present disclosure are applicable both on-axis boules 15 and/or off-axis boules 15A or other on-axis crystalline materials and/or off-axis crystalline materials.

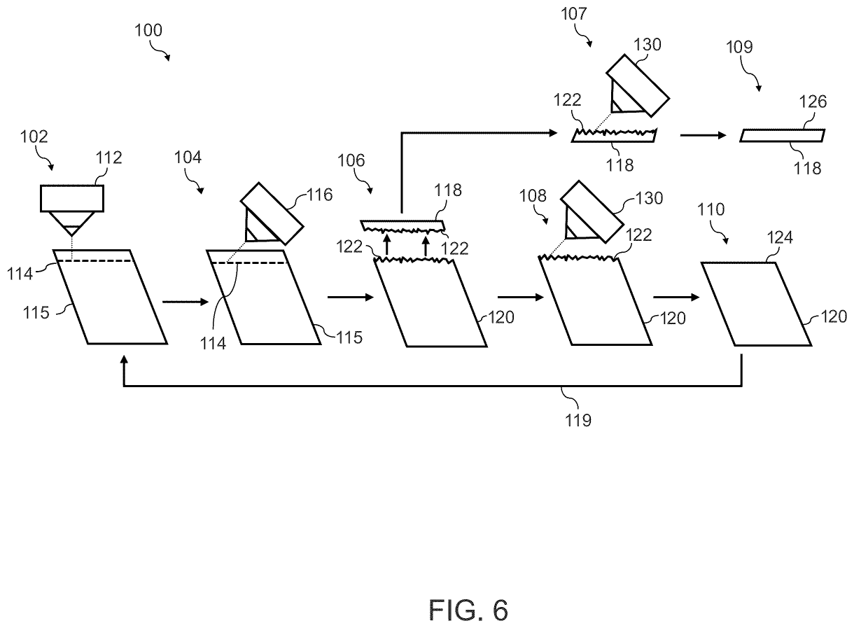

FIG. 6 depicts an overview of an example method 100 according to example embodiments of the present disclosure. FIG. 6 is intended to represent structures for identification and description and is not intended to represent the structures to physical scale. The method 100 includes operations illustrated in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

At 102, the method 100 may include providing a semiconductor workpiece 115, such as a semiconductor boule, with a subsurface damage region 114. The subsurface damage region 114 may be the result of an induced subsurface damage process performed on the semiconductor workpiece 115. The semiconductor workpiece 115 may be similar to the boule 15 or the off-axis boule 15A of FIGS. 5A and 5C respectively. The induced subsurface damage process may be a laser-based removal process or other induced subsurface damage process (e.g., ion implantation induced subsurface damage process). For instance, in some examples, one or more radiation source(s) 112 (e.g., a laser-based radiation source) may be operated (e.g., at a perpendicular incidence angle) to provide a damage-inducing emission of radiation to induce a subsurface damage region 114 in the semiconductor workpiece 115.

Referring to FIG. 6 at 104, the method 100 may include performing a treatment process on the subsurface damage region 114 of the semiconductor workpiece 115. The treatment process may include one or more radiation source(s) 116 that provide a treatment emission of radiation to the subsurface damage region 114 of the semiconductor workpiece 115. In some embodiments, the one or more radiation source(s) 116 that perform the treatment process may be operated to provide a treatment emission of radiation at a non-perpendicular incidence angle relative to the surface of the semiconductor workpiece 115, or non-perpendicular to the horizontal crack propagation that will occur in the subsurface damage region in a subsequent removal or separation process. In some embodiments, the non-perpendicular angle may be about 75° or less, such as about 30° or less, such as about 15° or less.

In some embodiments, the one or more radiation source(s) 116 that provide the treatment emission of radiation in the treatment process may differ from the one or more radiation source(s) 112 that induce the subsurface damage region 114. For example, in embodiments where the one or more radiation source(s) 112 that induce the subsurface damage region 114 are laser-based radiation source(s), the one or more sources of radiation 116 that provide the treatment emission of radiation in the treatment process may include one or more of a gas discharge source(s), incandescent radiation source(s), electroluminescence emitter(s), electronic or magnetic oscillator(s), free electron resonator(s), x-ray emitter(s), or bremsstrahlung emitter(s), by non-limiting example.

In some examples, the treatment emission of the radiation source 116 may be operated in accordance with the following laser radiation source 116 parameters:
Laser wavelength: about 190 nanometers to about 1100 nanometers, such as about 190 nanometers to about 300 nanometers, such as about 193 nanometers, such as about 200 nanometers, such as about 248 nanometers, such as about 266 nanometers, such as about 343 nanometers, such as about 355 nanometers, such as about 405 nanometers, such as about 532 nanometers, such as about 1064 nanometers, such as about 1064 nanometers, such as about 1080 nanometers, such as about 600 nanometers or less, such as 543 nanometers or less, 532 nanometers or less, 500 nanometers or less, 480 nanometers or less, 375 nanometers or less, 358 nanometers or less, 337 nanometers or less, 193 nanometers or less, 126 nanometers or less; or multiple wavelengths (e.g., white light) including any of the foregoing;
Laser pulse frequency: continuous or about 0.1 kilohertz to about 20 megahertz, such as about 10 kilohertz to about 150 kilohertz, such as about 20 kilohertz to about 20 megahertz;
Laser power: 0.1 watts to about 500 watts, such as about 0.5 watts to about 100 watts, such as about 1 watt to about 40 watts, such as about 1 watt to about 10 watts;
Laser pulse duration: in some examples, the laser pulse duration may be a continuous wave or a pulsed laser; in some examples the laser pulse duration may occur in a microsecond range, a picosecond range, or a femtosecond range; such as about 0.1 femtoseconds to about 300 nanoseconds; such as about 1 femtosecond to about 500 picoseconds, such as about 1 femtosecond to about 150 nanoseconds, such as about 1 femtosecond to about 100 nanoseconds;
Translation speed: about 1 millimeter per second to about 2 meters per second, such as about 1 millimeter per second to about 1 meter per second;
Focusing depth: about 0 microns to about 2000 microns (beneath the surface of the workpiece), such as about 0 microns to about 1000 microns (beneath the surface of the workpiece), such as about 1 micron to about 100 microns (beneath the surface of the workpiece), such as about 0 microns to about 5 microns (beneath the surface of the workpiece), such as about 0 microns to about 1 micron (beneath the surface of the workpiece).
Laser Pulse Energy: about 1 nanojoule to about 2 joules, such as about 10 nanojoules to about 200 millijoules.

In some embodiments, the one or more radiation source(s) 116 may provide the treatment emission of radiation at any angle relative to the angle at which the damage-inducing emission of radiation is provided by the one or more radiation source(s) 112. That is, in some examples, the one or more radiation source(s) 112 may provide the damage-inducing emission of radiation at specific angles, such as perpendicular to the surface of the semiconductor workpiece 115, while the one or more source(s) of radiation 116 may provide the treatment emission of radiation at an angle of about 0° to about 90°, such as about 75° or less, such as about 30° or less, such as about 15° or less, or at a plurality of incidence angles simultaneously relative to the angle at which the damage-inducing emission of radiation is provided to the semiconductor workpiece 115 by the one or more radiation source(s) 112.

In some examples, the treatment emission of the one or more radiation source(s) 116 that provide the treatment emission of radiation may be operated based on material properties of the workpiece 115 or the subsurface damage region 114. For example, the material properties may include differences in electrical conductivity, vibrational modes, electronic transition states, diffraction properties, absorption properties, or other properties of the workpiece 115 that are altered as a result of the subsurface damage region 514 with respect to an undamaged structure in the workpiece 515.

At 106, the method may include removing a first portion 118 of the semiconductor workpiece 115 from a second portion 120 of the semiconductor workpiece 115 along the subsurface damage region 114. In some examples, separation of the first portion 118 of the semiconductor workpiece 115 from the second portion 120 of the semiconductor workpiece 115 may be provided by the treatment process at 104 through modification of the subsurface damage region 114. At 106, a removal process may yield the first portion 118 of the semiconductor workpiece 115 and the second portion 120 of the semiconductor workpiece 115. The removal process at 106 may be performed through a variety of methods. For instance, a mechanical fracturing process, ultrasonic fracturing process, or other fracturing process may be used to fracture and remove the first portion 118 of the semiconductor workpiece 115 from the second portion 120 of the semiconductor workpiece 115.

In some examples, as a result of the treatment process at 104, the separation of the first portion 118 of the semiconductor workpiece 115 may reduce the surface roughness of a newly exposed surface on both the first portion 118 of the semiconductor workpiece 115 and the second portion 120 of the semiconductor workpiece 115 relative to the surface roughness of a first and a second portion of a semiconductor workpiece that do not undergo a treatment process. For instance, the first portion 118 of the semiconductor workpiece 115 may have an exposed surface 122 with low surface roughness, such as a surface roughness of less than about 10 microns to less than about 100 microns. Similarly, the second portion may have an exposed surface 122 with lower surface roughness, such as a surface roughness less than about 10 microns to less than about 100 microns.

Further processing may be performed on either the first portion 118 or the second portion 120 of the semiconductor workpiece 115. Further processing operations may remove portions of the exposed surface and/or provide a smoother surface suitable for later fabrication operations. As one example, as shown at 108, the method 100 may include ablating the exposed surface 122 of the second portion 120 of the semiconductor workpiece 115 using one or more off-axis lasers (e.g., at a non-perpendicular incidence angle or a perpendicular incidence angle may be utilized) of a laser system 130 to remove material from the exposed surface 122. The laser process(s) may result in a smoother exposed surface 124 of the second portion 120 of the semiconductor workpiece 115 as shown at 110.

By processing the exposed surface 122 of the second portion 120 of the semiconductor workpiece 115 with the laser system 130 as shown at 108, the second portion 120 of the semiconductor workpiece 115 may be suitable to be reused for subsequent induced subsurface damage processes as indicated by arrow 119. More particularly, the second portion 120 of the semiconductor workpiece 115 may be smoothed for a subsequent fracturing operation or to reduce the effort or total material removal requirement of subsequent surface smoothing operations. For instance, a rough surface on the second portion 120 of the semiconductor workpiece 115 may lead to undesirable reflection/refraction of one or more laser(s) used during formation of the subsurface laser damage regions for removal of subsequent portions of the semiconductor workpiece 115. Further processing techniques performed at 108 are not limited to the laser system 130, a laser system is illustrated for purposes of discussion and to facilitate understanding of the method 100. In some examples, additional surface processing operations may occur on the second portion 120 of the semiconductor workpiece 115 prior to subsequent smoothing processes (e.g., grinding, polishing, lapping, etc.).

As another example, as shown at 107, the method 100 may include ablating the exposed surface 122 of the first portion 118 of the semiconductor workpiece 115 using one or more off-axis lasers (e.g., a non-perpendicular incidence angle or a perpendicular incidence angle may be utilized) of a laser system 130 to remove material from the exposed surface 122. The surface processing operation may result in a smoother exposed surface 126 of the first portion 118 of the semiconductor workpiece 115 as shown at 109. In some examples, the processed surface has a post-processed surface roughness in a range of about 0.5 nanometers to about 350 nanometers. Accordingly, the first portion 118 of the semiconductor workpiece 115 may be suitable for subsequent semiconductor device fabrication operations.

In some embodiments, the first portion 118 or the second portion 120 of the semiconductor workpiece 115 may be subject to additional planarization techniques or non-destructive modifications of surface properties of the first portion 118 or the second portion 120 of the workpiece 115 before further processing operations, such as the ablation of the exposed surface(s) 122 at 107. For example, in some embodiments, a filler material may be applied to a surface (e.g., an exposed surface 122, or other surface) of the first portion 118 or the second portion 120 of the semiconductor workpiece 115 which may fill any deep topographical areas and/or cover any topographical peaks to create a planarized surface on the first portion 118 or the second portion 120 of the semiconductor workpiece 115. The planarized surface with the filler material has a surface roughness that is less than a surface roughness of the surface prior to application of the filler material. In some embodiments, the first portion 118 or the second portion 120 of the semiconductor workpiece 115 can be coated or immersed in a fluid such that the optical properties differ from the optical properties of the atmosphere during further processing operations, such as the ablation of the exposed surface 122 at 107.

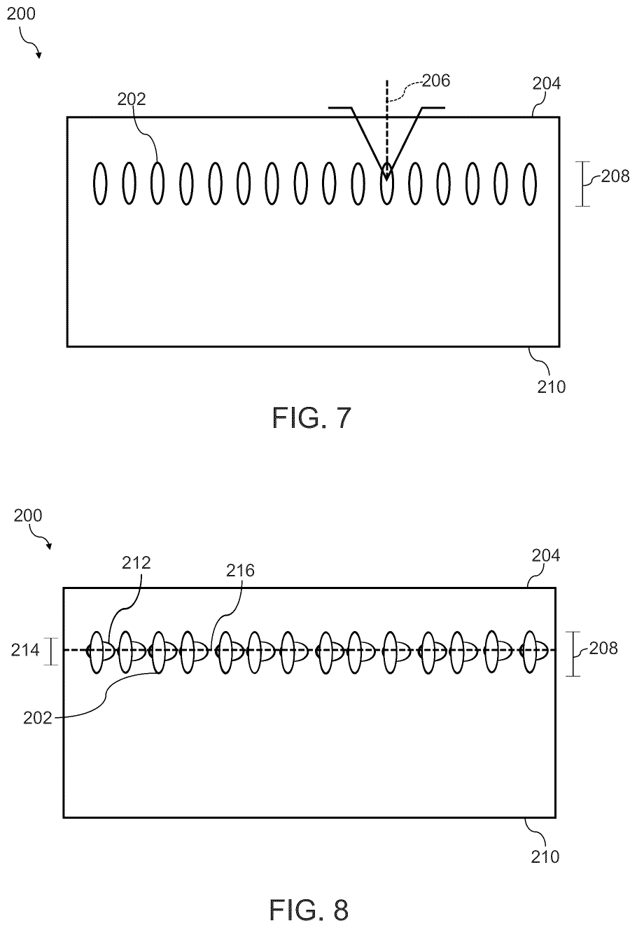

FIG. 7 is a cross-sectional schematic view of a crystalline material workpiece 200, such as a silicon carbide crystalline workpiece, including a first subsurface damage pattern 202 centered at a first depth relative to a first surface 204 of the workpiece 200, with the subsurface damage pattern 202 produced by focused emissions of a laser 206. The first subsurface laser damage pattern 202 has a vertical extent 208 that remains within an interior of the workpiece 200 between the first surface 204 and an opposing second surface 210.

FIG. 8 is a cross-sectional schematic view of the workpiece 200 of FIG. 7 following formation of a second subsurface damage pattern 212 centered at a second depth and registered with the first subsurface damage pattern 202, wherein a vertical extent 214 of the second subsurface damage pattern 212 overlaps with the vertical extent 208 of the first subsurface damage pattern 202 in an overlapping subsurface damage region 216. In certain embodiments, subsequent fracturing of the workpiece 200 may be performed along or through the subsurface damage region 216. According to aspects of the present disclosure, the workpiece 200 that undergoes a treatment process, such as any of the treatment processes 104 discussed in the example method 100 of FIG. 6, may alter the geometry of the subsurface damage region 216 (e.g., the vertical extent 208, 214 or the overlapping subsurface damage region 216) which may lessen the impacts of undesirable vertical components where cracks may propagate in the subsurface damage region 216 during subsequent separation or removal processes. For instance, if the treatment emission of radiation from the radiation source 116 of FIG. 6 is modified with respect to the damage-inducing emission of radiation from the one or more radiation sources 112 of FIG. 6, the geometry of radiation exposure to the subsurface damage region 216 or orientation of the vertical extent 214 may be modified such that the resulting subsurface damage region 216 or the vertical extent 214 includes a larger horizontal dimension with respect to the surface 204, a shorter vertical dimension with respect to the surface 204, or an alteration of the orientation of the second damage pattern 212 with respect to the first damage pattern 202. That is, the second damage pattern may vary based on the mechanism (e.g., source type, optical parameters, operation parameters, etc.) which may cause the treatment emission of radiation to differ from the damage inducing emission of radiation. This may result in the second damage pattern 212 of the treatment emission of radiation exceeding (or being absorbed differently in) regions between the first damage pattern 202. This may reduce alignment requirements of the second damage pattern 212 with respect to the first damage pattern 202. It will be understood by one skilled in the art, using the disclosures provided herein, that the emission of radiation resulting in the second damage pattern 212 may be absorbed by the material in a variety of ways based on parameters of the radiation source and optical properties of the material. The second damage pattern 212 of FIG. 8 is provided for purpose of discussion and is provided to illustrate the second damage pattern 212 exhibiting changes in a dimensional component of the second damage pattern 212, different orientation or alignment with respect to the first damage pattern 202, or altered absorption properties of the emission of radiation producing the second damage pattern 212 by the workpiece 200. The second damage pattern 212 may exhibit one of these features, or a combination thereof.

In some embodiments, modification of the treatment emission of radiation from the radiation source 116 includes a modification such that the radiation exposure to the subsurface damage layer 216 occurs over a wider area of the subsurface damage layer 216 in comparison with radiation exposure occurring at orthogonal angles with the surface 204 of the workpiece 200. In some embodiments, the entirety of the workpiece 200 (e.g., the surface 204 or the first damage pattern 202) is illuminated from a single treatment emission of radiation from the radiation source.

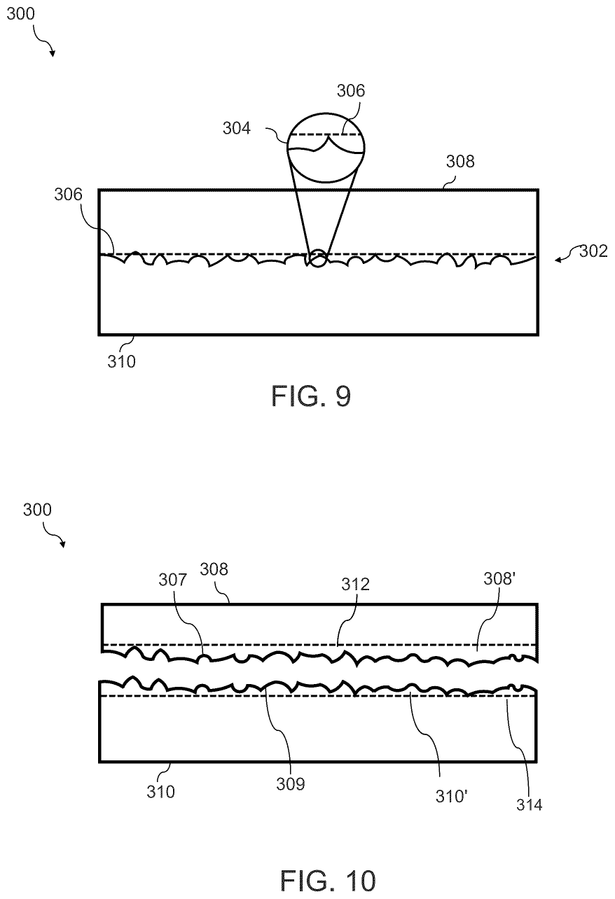

FIG. 9 depicts a cross-sectional representation of a semiconductor workpiece 300 showing the subsurface damage region 302 and resulting propagation of cracks in the subsurface damage region 302 according to examples of the present disclosure. Features of the subsurface damage region 302 are illustrated in the magnified view 304 of the subsurface damage region 302. As illustrated, the subsurface damage region 302 includes a maximum vertical component of crack propagation 306 in a potential separation or removal process that results in a valley depth in a first portion 308 or a peak height in a second portion 310 of the semiconductor workpiece 300 after a separation or a removal process. FIG. 10 depicts a cross-sectional representation of the semiconductor workpiece 300 that has been subjected to a separation or removal process along the subsurface damage region 302 of FIG. 9 according to examples of the present disclosure. As shown in FIG. 10, the semiconductor workpiece 300 has been separated along the subsurface damage region 302 leaving a rough exposed surface 307 on the first portion 308 of the semiconductor workpiece 300 and a rough exposed surface 309 on the second portion 310 of the semiconductor workpiece 300. The first portion 308 of the semiconductor workpiece 300 may include a removal portion 308′ that may be removed using laser ablation process(s) up to a removal point 312 to provide a smoother surface on the first portion 308 of the semiconductor workpiece 300. Similarly, the second portion 310 of the semiconductor workpiece 300 may include a removal portion 310′ that may be removed using laser ablation process(s) up to removal point 314 to provide a smoother surface on the second portion 310 of the semiconductor workpiece 300.

According to aspects of the present disclosure, as a result of the treatment process performed on the subsurface damage region 302 of FIG. 9, the removal portion 308′ of the first portion 308 of the semiconductor workpiece 300 and the removal portion 310′ of the second portion 310 of the semiconductor workpiece 300 may be reduced by reducing the vertical extent (e.g., the vertical extents 208 and/or 214 of FIGS. 7 and 8) of the propagation of cracks formed in the subsurface damage region 302 of FIG. 9 during a separation or removal process.

According to aspects of the present disclosure, as a result of the treatment process, such as the treatment process at 104 of FIG. 6, the separation of the first portion 308 of the semiconductor workpiece 300 may reduce the surface roughness of the newly exposed surfaces 307, 309 on both the first portion 308 of the semiconductor workpiece 300 and the second portion 310 of the semiconductor workpiece 300 relative to the surface roughness of newly exposed surfaces of a first and a second portion of a semiconductor workpiece that do not undergo a treatment process. For instance, in some embodiments, the first portion 308 of the semiconductor workpiece 300 may have the exposed surface 307 with low surface roughness, such as a surface roughness of less than about 10 microns to less than about 100 microns. Similarly, the second portion 310 of the semiconductor workpiece 300 may have the exposed surface 309 with lower surface roughness, such as a surface roughness less than about 10 microns to less than about 100 microns.

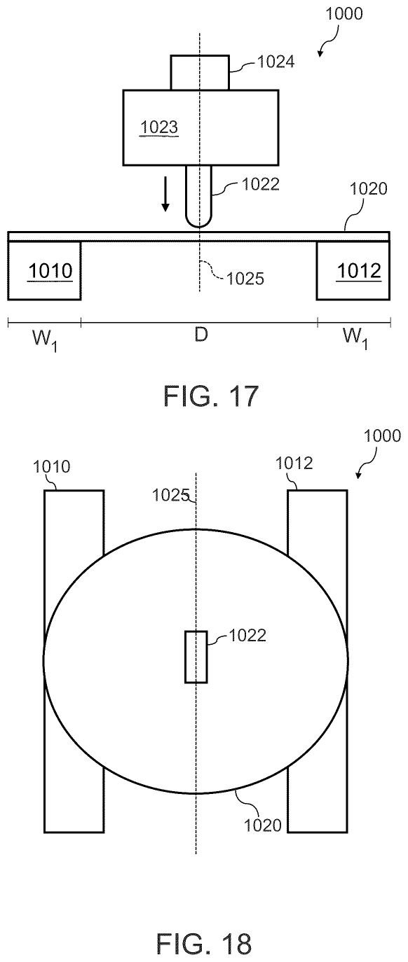

According to aspects of the present disclosure, the semiconductor workpiece 300 that has undergone a treatment process may exhibit increased fracture strength, which may be a result of the treatment process decreasing the severity of stress concentration areas formed by the peaks and valleys of the newly exposed surfaces 307, 309 after a separation process. In some embodiments, the treatment process may improve the fracture strength of the first or the second portions 308, 310 of the semiconductor workpiece 300, providing a fracture strength in a range of about 17.5 Newtons or greater, such as about 25 Newtons to about 75 Newtons. A technique for determining the fracture strength of a first or a second portion 308, 310 of the workpiece 300 is discussed in relation to FIGS. 17 and 18.

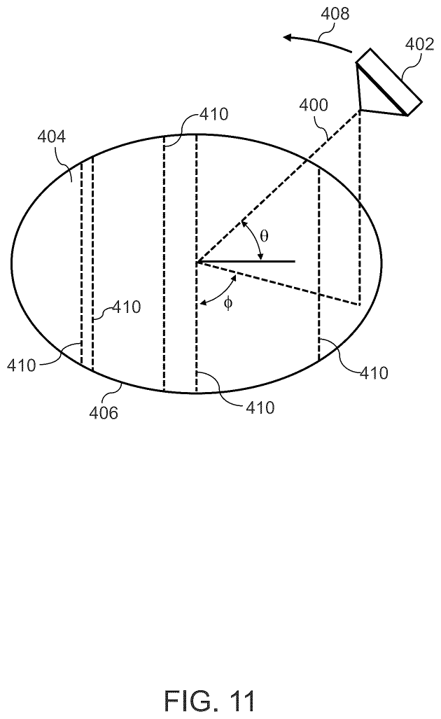

FIG. 11 depicts providing a treatment emission 400 of radiation from a radiation source 402 (e.g., a laser) at a non-perpendicular incidence angle relative to the surface 404 of the semiconductor workpiece 406. As used herein, providing the emission 400 of a radiation source 402 (e.g., the emission of a laser used in the treatment process) refers to both providing continuous emission and/or providing modulated emission (e.g., a plurality of radiation pulses). FIG. 11 is discussed with reference to providing the emission 400 of a radiation source 402 with respect to a surface 404 of the semiconductor workpiece 406 for purposes of illustration and discussion. However, the emission 400 of radiation may be provided across the surface of any semiconductor workpiece, such as the rough exposed surfaces 307, 309 of the first or the second portions 308, 310 of the semiconductor workpiece 300 of FIG. 10.

As shown in FIG. 11, the radiation source 402 may be configured (e.g., through one or more optics such as mirrors, lens, etc.) to provide an emission 400 of one or more radiation source(s) 402 at a non-perpendicular incidence angle θ, such as at an incidence angle θ of less than about 75°, such as less than about 45°, such as less than about 30°, such as less than about 15°. Providing the emission 400 of the radiation source 402 at a non-perpendicular incidence angle θ may reduce the impacts of the vertical extent of the subsurface damage region in a semiconductor workpiece, such as the vertical extents 208, 214 of the subsurface damage region 216 of FIGS. 7 and 8.

In some embodiments, the incidence angle θ of the emission 400 of the radiation source 402 relative to the surface 404 may be adjusted during the treatment process. For instance, during a first pass of the emission 400 of the radiation source 402 at a fixed focal depth the radiation source 402 may be configured to provide the emission 400 of one or more lasers at a first incidence angle θ (e.g., non-perpendicular incidence angle). During a second pass or subsequent pass of the emission 4002 of the radiation source 402 at a fixed focal depth the radiation source 402 may be configured to provide the emission 400 of one or more lasers at a second incidence angle θ (e.g., non-perpendicular incidence angle, not pictured to change in FIG. 11). In some embodiments, the incidence angle θ of the emission 400 of the radiation source 402 may be controlled as indicated by arrow 408 to be closer and closer to a perpendicular incidence angle with each subsequent pass of the emission 400 of the radiation source 402 on the surface 404. In some embodiments, the incidence angle θ of the emission 400 of the radiation source 402 may be adjusted based at least in part on data indicative of the surface roughness of the surface 404 (e.g., obtained from one or more sensors) and/or based on data indicative of a damage depth in the semiconductor workpiece 406. In some embodiments, the incidence angle θ of the emission 400 of the radiation source 402 may be adjusted based at least in part on a damage depth of the semiconductor workpiece 406. In some embodiments, the incidence angle θ of the emission 400 of the radiation source 402 may be oscillating in a regular or irregular manner.

In some examples, the emission 400 of the radiation source 402 may be operated in accordance with the following laser-based radiation source 402 parameters:
Laser wavelength: about 190 nanometers to about 1100 nanometers, such as about 190 nanometers to about 300 nanometers, such as about 193 nanometers, such as about 200 nanometers, such as about 248 nanometers, such as about 266 nanometers, such as about 343 nanometers, such as about 355 nanometers, such as about 405 nanometers, such as about 532 nanometers, such as about 1064 nanometers, such as about 1064 nanometers, such as about 1080 nanometers, such as about 600 nanometers or less, such as 543 nanometers or less, 532 nanometers or less, 500 nanometers or less, 480 nanometers or less, 375 nanometers or less, 358 nanometers or less, 337 nanometers or less, 193 nanometers or less, 126 nanometers or less; or multiple wavelengths (e.g., white light) including any of the foregoing;
Laser pulse frequency: continuous to about 0.1 kilohertz to about 20 megahertz, such as about 10 kilohertz to about 150 kilohertz, such as about 20 kilohertz to about 20 megahertz;
Laser power: 0.1 watts to about 500 watts, such as about 0.5 watts to about 100 watts, such as about 1 watt to about 40 watts, such as about 1 watt to about 10 watts;
Laser pulse duration: in some examples, the laser pulse duration may be a continuous wave or a pulsed laser; in some examples the laser pulse duration may occur in a microsecond range, a picosecond range, or a femtosecond range; such as about 0.1 femtoseconds to about 300 nanoseconds; such as about 1 femtosecond to about 500 picoseconds, such as about 1 femtosecond to about 150 nanoseconds, such as about 1 femtosecond to about 100 nanoseconds;
Translation speed: about 1 millimeter per second to about 2 meters per second, such as about 1 millimeter per second to about 1 meter per second;
Focusing depth: about 0 microns to about 2000 microns (beneath the surface of the workpiece), such as about 0 microns to about 1000 microns (beneath the surface of the workpiece), such as about 1 micron to about 100 microns (beneath the surface of the workpiece), such as about 0 microns to about 5 microns (beneath the surface of the workpiece), such as about 0 microns to about 1 micron (beneath the surface of the workpiece).
Laser Pulse Energy: about 1 nanojoule to about 2 joules, such as about 10 nanojoules to about 200 millijoules.

The radiation source 402 may provide the emission 400 (e.g., continuous emission and/or pulsed emission) of the radiation at one or more non-perpendicular incidence angles across the surface 404 of the semiconductor workpiece 406.

The surface 404 may be scanned by the emission 400 of the radiation source 402 in one or more pass. Each pass of the emission 400 of the radiation source 402 may have a scan dimension (e.g., spot size, focus area) representative of a dimension of the emission 400 of the radiation source 402 on the surface 404. The scan dimension (e.g., spot size, focus area) may be in a range of, for instance, 10 microns to about 25 millimeters, such as about 500 microns to about 25 millimeters, such as about 1 millimeter to about 25 millimeters, such as about 1 millimeter to about 10 millimeters. In some examples, there may be a distance between passes of the emission 400 of radiation from the radiation source 402. The distance between each scan or pass may be, for instance, in a range of about 0 millimeters to about 1 millimeter, such as about 0 millimeters to about 500 microns. In some examples, there may be no distance between passes of the emission 400 of radiation from the radiation source 402. In some examples there may be overlap between scans or passes of the emission 400 of radiation from the radiation source 402 on the surface 404. In some examples, there may be about 0% to about 50% overlap of the scan dimension (e.g. spot size) between passes of the emission 400 of radiation from the radiation source 402.

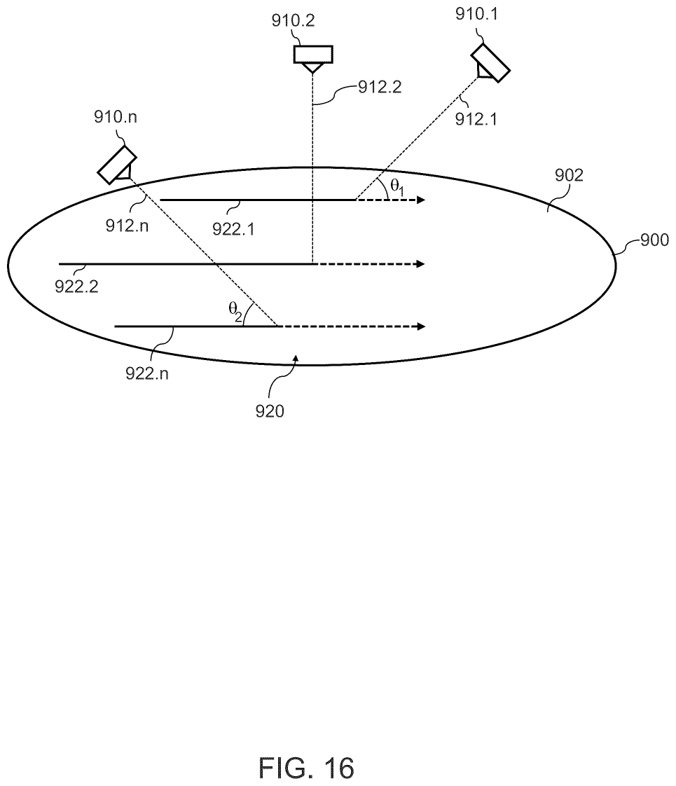

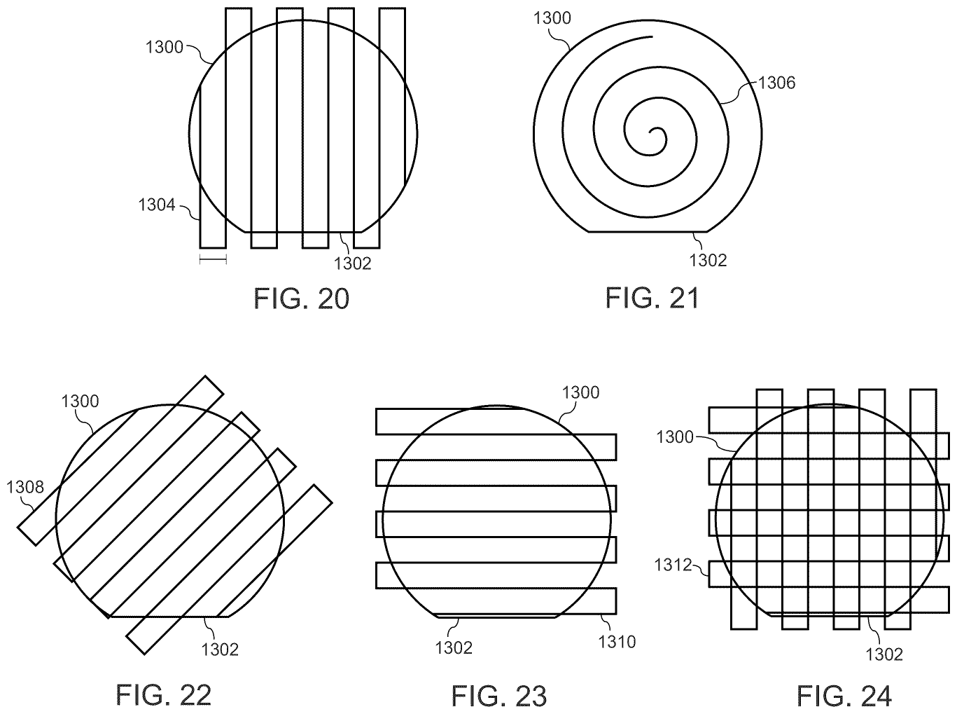

Example scan patterns are provided in FIGS. 20-26 below. In addition, FIG. 11 depicts a single emission 400 of radiation from the radiation source 402 emitted onto the surface 404 of the semiconductor workpiece 406. The one or more radiation source(s) 402 (e.g., at distinct incidence angles) may provide emissions 400 of radiation onto the surface 404 of the semiconductor workpiece 406 as shown in FIG. 16 below without deviating from the scope of the present disclosure.

In some examples, a semiconductor workpiece 406 may include step structures 410 illustrated in FIG. 11 that are relative to the c-axis basal plane. The step structures 410 may result from alterations (e.g., fracturing, amorphization, decomposition, etc.) of an off-axis semiconductor workpiece 406 (e.g., boule 15A of FIG. 5C). In some examples, the emission 400 of the radiation source 402 may be emitted relative to a length of a step structure 410 such that a projection of the emission 400 of the radiation source 402 onto the surface 404 of the semiconductor workpiece 406 forms a scan angle φ relative to the length of the step structure 410. In some embodiments, the scan angle φ may be a generally perpendicular angle. However, the scan angle φ may be any angle without deviating from the scope of the present disclosure.

In some embodiments, the emission 400 of radiation from the radiation source 402 may scan the surface 404 in a direction generally perpendicular to a length of the step structures 410 relative to the c-axis basal plane (e.g., the scan angle φ is within 15° of 90°). In some examples, the emission 400 of radiation from the radiation source 402 may scan the surface 404 in a direction generally parallel to a length of the step structures 410 relative the c-axis basal plane (e. g,, the scan angle φ is 0° or within 15° of 0°). In some examples, the emission 400 of radiation from the radiation source 402 may scan the surface 404 in a direction that is not perpendicular and not parallel to a length of the step structures 410 relative to the c-axis basal plane (e.g., the scan angle is in a range of about 20° to about 70°). In some examples, the scan angle φ may be adjusted (e.g., during scanning of the workpiece 406) based on one or more workpiece properties and or surface topography of the workpiece 406. For instance, the scan angle φ may be adjusted to remain generally perpendicular to a length of one or more trenches or other features in the workpiece 406.

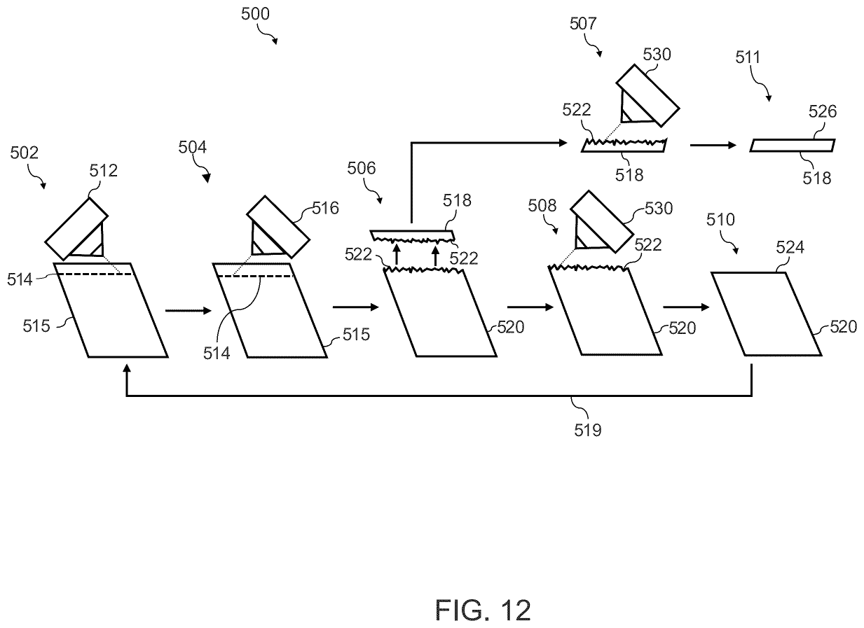

FIG. 12 depicts an overview of an example method 500 according to example embodiments of the present disclosure. FIG. 12 is intended to represent structures for identification and description and is not intended to represent the structures to physical scale. The method 500 includes operations illustrated in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

At 502, the method 500 may include providing a semiconductor workpiece 515, such as a semiconductor boule. In some embodiments, the semiconductor workpiece 515 may be subjected to a subsurface-damage inducing emission of radiation from one or more radiation source(s) 512 at a non-perpendicular incidence angle relative to the surface of the semiconductor workpiece 515. The non-perpendicular angle of the subsurface-damage inducing emission of radiation from the one or more radiation sources 512 may be provided at an angle of less than about 75°, such as less than about 45°, such as less than about 30°, such as less than about 15°. The semiconductor workpiece 515 may be similar to the boule 15 or the off-axis boule 15A of FIGS. 5A and 5C respectively.

Referring to FIG. 12 at 504, the method 500 may include performing a treatment process on the subsurface damage region 514 of the semiconductor workpiece 115. The treatment process may include one or more radiation source(s) 516 that provide a treatment emission of radiation to the subsurface damage region 514 of the semiconductor workpiece 515. In some embodiments, the one or more radiation source(s) 516 that perform the treatment process may be operated to provide a treatment emission of radiation at a non-perpendicular incidence angle relative to the surface of the semiconductor workpiece 515, or non-perpendicular to the horizontal crack propagation that will occur in the subsurface damage region 514 in a subsequent removal or separation process. The non-perpendicular angle of the treatment emission of radiation from the one or more radiation sources 516 may be provided at an angle of less than about 75°, such as less than about 45°, such as less than about 30°, such as less than about 15°.

In some embodiments, the one or more radiation source(s) 516 that provide the treatment emission of radiation in the treatment process may differ from the one or more radiation source(s) 512 that induce the subsurface damage region 514. That is, in embodiments where the one or more radiation source(s) 512 that induce the subsurface damage region 514 are laser-based radiation source(s), the one or more sources of radiation 516 that provide the treatment emission of radiation in the treatment process may include one or more of a gas discharge source(s), an incandescent radiation source(s), an electroluminescence emitter(s), an electronic or magnetic oscillator(s), a free electron resonator(s), an x-ray emitter(s), or a bremsstrahlung emitter(s), by non-limiting example. In some embodiments, the one or more radiation source(s) 516 that provide the treatment emission of radiation may be provided at any angle relative the angle at which the damage-inducing emission of radiation is provided.

In some examples, the treatment emission of the one or more radiation source(s) 516 that provide the treatment emission of radiation may be operated based on material properties of the workpiece 515 or the subsurface damage region 514. For example, the material properties may include differences in electrical conductivity, vibrational modes, electronic transition states, diffraction properties, absorption properties, or other properties of the workpiece that are altered as a result of the subsurface damage region 514 with respect to an undamaged structure in the workpiece 515.

At 506, the method may include separating a first portion 518 of the semiconductor workpiece 515 from a second portion 520 of the semiconductor workpiece 515 along the subsurface damage region 514. Removing the first portion 518 from the semiconductor workpiece 515 may be performed through a variety of methods. For instance, a mechanical fracturing process, ultrasonic fracturing process, or other fracturing process may be used to fracture and separate the first portion 518 of the semiconductor workpiece 515 from the second portion 520 of the semiconductor workpiece 515.

In some examples, as a result of the treatment process at 504, the separation of the first portion 518 of the semiconductor workpiece 515 may reduce the surface roughness of a newly exposed surface 522 on both the first portion 518 of the semiconductor workpiece 515 and the second portion 520 of the semiconductor workpiece 515 relative to the surface roughness of a first and a second portion of a semiconductor workpiece that do not undergo a treatment process. For instance, the first portion 518 of the semiconductor workpiece 515 may have the exposed surface 522 with low surface roughness, such as a surface roughness of less than 10 microns to about 100 microns. Similarly, the second portion 520 may have the exposed surface 522 with lower surface roughness, such as a surface roughness less than about 10 microns to less than about 100 microns.

Further processing may be performed on either the first portion 518 or the second portion 520 of the semiconductor workpiece 515. Further processing operations may remove portions of the exposed surface and/or provide a smoother surface suitable for later fabrication operations. As one example, as shown at 508, the method 500 may include ablating the exposed surface 522 of the second portion 520 of the semiconductor workpiece 515 using one or more off-axis lasers (e.g., at a non-perpendicular incidence angle) of a laser system 530 to remove material from the exposed surface 522. The laser ablation process(s) may result in a smoother exposed surface 524 of the second portion 520 of the semiconductor workpiece 515 as shown at 510.

By processing the exposed surface 522 of the second portion 520 of the semiconductor workpiece 515 with the laser system 530 as shown at 508, the second portion 520 of the semiconductor workpiece 515 may be suitable to be reused for subsequent induced subsurface damage processes as indicated by arrow 519. More particularly, the second portion 520 of the semiconductor workpiece 515 may be smoothed for a subsequent fracturing operation or to reduce the effort or total material removal requirement of subsequent surface smoothing operations. For instance, a rough surface on the second portion 520 of the semiconductor workpiece 515 may lead to undesirable reflection/refraction of one or more laser(s) used during formation of the subsurface laser damage regions for removal of subsequent portions of the semiconductor workpiece 515. Further processing techniques performed at 508 are not limited to the laser system 530, a laser system is illustrated for purposes of discussion and to facilitate understanding of the method 500. In some examples, additional surface processing operations may occur on the second portion 520 of the semiconductor workpiece 515 prior to subsequent smoothing processes (e.g., grinding, polishing, lapping, etc.).

As another example, as shown at 507, the method 500 may include ablating the exposed surface 522 of the first portion 518 of the semiconductor workpiece 515 using one or more off-axis lasers of a laser system 530 to remove material from the exposed surface 522. The laser-based surface processing operation may result in a smoother exposed surface 526 of the first portion 518 of the semiconductor workpiece 515 as shown at 509. Accordingly, the first portion 518 of the semiconductor workpiece 515 may be suitable for subsequent semiconductor device fabrication operations.

In some embodiments, the first portion 518 or the second portion 520 of the semiconductor workpiece 515 may be subject to additional planarization techniques or non-destructive modifications of surface properties of the first portion 518 or the second portion 520 of the workpiece 515 before further processing operations, such as the ablation of the exposed surface(s) 522 at 507. For example, in some embodiments, a filler material may be applied to a surface (e.g., an exposed surface 522, or other surface) of the first portion 518 or the second portion 520 of the semiconductor workpiece 515 which may fill any deep topographical areas and/or cover any topographical peaks to create a planarized surface on the first portion 518 or the second portion 520 of the semiconductor workpiece 515. The planarized surface with the filler material has a surface roughness that is less than a surface roughness of the surface prior to application of the filler material. In some embodiments, the first portion 518 or the second portion 520 of the semiconductor workpiece 515 can be coated or immersed in a fluid such that the optical properties differ from the optical properties of the atmosphere during further processing operations, such as the ablation of the exposed surface 522 at 507.

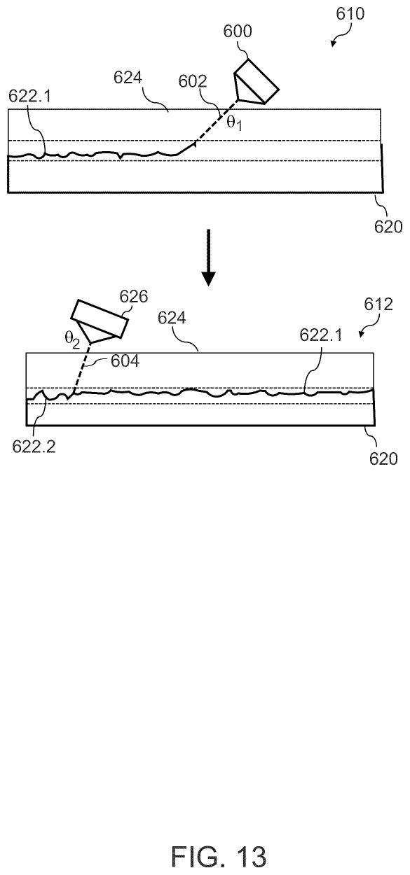

FIG. 13 depicts example subsurface damage region processing of a semiconductor workpiece 620 according to examples of the present disclosure. As shown in FIG. 13, a first pass 610 of the damage inducing emission 602 of radiation may be implemented on the semiconductor workpiece 620 to provide a subsurface damage region 622 using a radiation source 600 (e.g., a laser-based radiation source) at a non-perpendicular incidence angle θ₁ relative to the surface 624. In some examples, the radiation source 600 configured to induce a subsurface damage region in the workpiece 620 is a laser-based radiation source. The radiation source 600 may include one or more lenses, mirrors, or other optics to focus the emission 602 at a particular focal depth below the surface 624 and at a particular non-perpendicular incidence angle θ₁. The radiation source 600 may provide emission 602 of radiation with sufficient power, pulsing frequency, and pulse duration to alter material in a desired subsurface damage region 622 to yield a first subsurface damage region 622.1.

In some examples, the damage-inducing emission 602 of the radiation source 600 may be operated in accordance with the following damage-inducing radiation source 600 parameters:
Laser wavelength: about 190 nanometers to about 1100 nanometers, such as about 190 nanometers to about 300 nanometers, such as about 193 nanometers, such as about 200 nanometers, such as about 248 nanometers, such as about 266 nanometers, such as about 343 nanometers, such as about 355 nanometers, such as about 405 nanometers, such as about 532 nanometers, such as about 1064 nanometers, such as about 1064 nanometers, such as about 1080 nanometers; or multiple wavelengths (e.g., white light) including any of the foregoing;
Laser pulse frequency: about 0.1 kilohertz to about 200 kilohertz, such as about 10 kilohertz to about 150 kilohertz, such as about 20 kilohertz to about 100 kilohertz;
Laser power: 0.1 watts to about 500 watts, such as about 0.5 watts to about 100 watts, such as about 1 watt to about 40 watts, such as about 1 watt to about 10 watts;
Laser pulse duration: about 0.1 femtoseconds to about 300 nanoseconds; such as about 1 femtosecond to about 500 picoseconds, such as about 1 femtosecond to about 150 nanoseconds, such as about 1 femtosecond to about 100 nanoseconds;
Translation speed: about 1 millimeter per second to about 2 meters per second, such as about 1 millimeter per second to about 1 meter per second
Focusing depth: about 0 microns to about 2000 microns (beneath the surface of the workpiece), such as about 0 microns to about 1000 microns (beneath the surface of the workpiece), such as about 1 micron to about 100 microns (beneath the surface of the workpiece), such as about 0 microns to about 5 microns (beneath the surface of the workpiece), such as about 0 microns to about 1 micron (beneath the surface of the workpiece).
Laser Pulse Energy: about 1 nanojoule to about 2 joules, such as about 10 nanojoules to about 200 millijoules.

As shown in FIG. 13, after a first pass 610 of the subsurface damage inducing operation, a second pass 612 of the subsurface processing operation may be implemented on the subsurface damage region 622.1 using a radiation source 626. The radiation source 626 is configured to provide a treatment emission 604 of radiation to the subsurface damage region 622.1. The radiation source 626 may include one or more lenses, mirrors, or other optics to focus the emission 604 of radiation at a particular focal depth on the subsurface damage region 622.1 and/or at a particular non-perpendicular incidence angle θ₂ relative to the surface 624. The radiation source 626 may provide emission 604 of radiation with sufficient power, pulsing frequency, and pulse duration to alter material (e.g., silicon carbide) at the subsurface damage region 622.1 to yield a second subsurface damage region 622.2 with reduced vertical features indicated by the dashed lines.

In some examples, the non-perpendicular incidence angle θ₂ may be different from the non-perpendicular incidence angle θ₁. For instance, the non-perpendicular incidence angle θ₂ may be closer to perpendicular than the non-perpendicular incidence angle θ₁. This may facilitate the alteration of material at differing vertical points in the subsurface damage region 622.1.

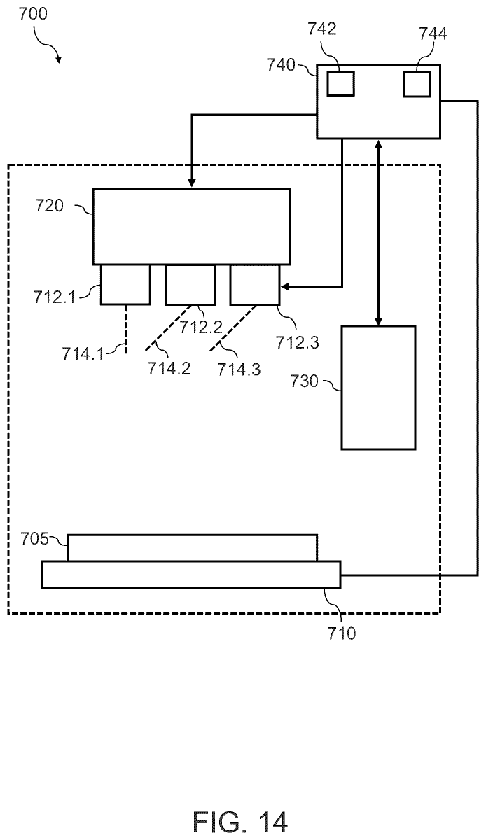

FIG. 14 depicts an example radiation-based processing system 700 according to examples of the present disclosure. The radiation-based processing system 700 may be configured to implement one or more aspects of the present disclosure, such as the off-axis laser-based processing operations provided herein and/or laser-based removal processes including a radiation-based treatment process for removing a first and/or a second portion of a semiconductor workpiece. The radiation-based processing system 700 may include one or more coherent or incoherent radiation sources, such as one or more of a laser-based radiation source(s), gas discharge source(s), incandescent radiation source(s), electroluminescence emitter(s), electronic or magnetic oscillator(s), free electron resonator(s), x-ray emitter(s), or bremsstrahlung emitter(s), by non-limiting example. The coherent or incoherent radiation sources may be operated under the same, or differing processing parameters based on the radiation source.

For example, the radiation-based processing system 700 may be a coherent radiation-based processing system, such as a laser-based processing system. The laser-based processing system may include one or more laser sources 712.1, 712.2, 712.3, . . . , 712.n. The one or more laser sources 712.1, 712.2, 712.3, . . . , 712.n may each be configured to respectively emit a laser 714.1, 714.2, 714.3, . . . , 714.n in accordance with various laser parameters. The laser parameters may include, for instance, focusing depth, laser power, laser wavelength, laser pulse duration, laser pulse frequency, laser pulse energy, laser incidence angle, scan pattern, scan angle (e.g., relative to surface topography, such as step structures), etc. For instance, each of the one or more laser sources 712.1, 712.2, 712.3 . . . , 712.n may be configured to emit lasers 714.1, 714.2, 714.3, . . . , 714.n at a non-perpendicular and/or a perpendicular incidence angle relative to the surface of a workpiece 705.

The laser sources 712.1, 712.2, 712.3, . . . , 712.n may each be associated with one or more wavelengths and may be, for instance, one or more of an excimer laser, UV laser, visible light laser, infrared laser, single wavelength laser, multiwavelength laser, white laser, etc. The laser sources 712.1, 712.2, 712.3, . . . , 712.n may each be associated with a pulse duration and may be one or more of an attosecond laser, femtosecond laser, nanosecond laser, etc. The laser sources 712.1, 712.2, 712.3, . . . , 712.n may each be associated with a lasing medium and may be, for instance, a gas (e.g., CO2) laser, solid state laser (e.g., GaN, AlGaN, YAG, etc.), diode laser, fiber laser, etc. The laser sources 712.1, 712.2, 712.3, . . . , 712.n may be one or more of a single frequency laser, frequency doubled laser, frequency tripled laser, frequency quadrupled laser, etc.

The laser sources 712.1, 712.2, 712.3, . . . , 712.n may each be the same type of laser source or different types of laser sources. The laser sources 712.1, 712.2, 712.3, . . . , 712.n may be configured to emit lasers 714.1, 714.2, 714.3, . . . , 714.n in accordance with the same laser parameters or different laser parameters.

For instance, in some embodiments, the radiation-based processing system 700 may include a first laser source 712.1, a second laser source 712.2, and a third laser source 712.3. In some embodiments, the first laser source 712.1 may be operable to emit a laser 714.1 with laser parameters sufficient to perform a laser-based subsurface damage process, such as the laser-based subsurface damage process shown at 102 of FIG. 6. The first laser source 712.1 may be operable to emit a laser 714.1 at a first incidence angle (e.g., generally perpendicular or non-perpendicular incidence angle).

The second laser source 712.2 may be operable to emit a laser 714.2 with laser parameters sufficient to perform a laser-based subsurface damage region treatment operation according to examples of the present disclosure. In some examples, the second laser source 712.2 may be operable to emit a laser 714.2 at a second incidence angle (e.g., generally perpendicular or non-perpendicular incidence angle). In some embodiments, the second laser source 712.2 may be configured to emit a second laser 714.2 in accordance with the following laser parameters:
Laser wavelength: about 190 nanometers to about 1100 nanometers, such as about 190 nanometers to about 300 nanometers, such as about 193 nanometers, such as about 200 nanometers, such as about 248 nanometers, such as about 266 nanometers, such as about 343 nanometers, such as about 355 nanometers, such as about 405 nanometers, such as about 532 nanometers, such as about 1064 nanometers, such as about 1080 nanometers; or multiple wavelengths (e.g., white light) including any of the foregoing;
Laser pulse frequency: continuous or about 0.1 kilohertz to about 20 megahertz, such as about 10 kilohertz to about 150 kilohertz, such as about 20 kilohertz to about 100 kilohertz;
Laser power: 0.1 watts to about 500 watts, such as about 0.5 watts to about 100 watts, such as about 1 watt to about 40 watts, such as about 1 watt to about 10 watts;
Laser pulse duration: the laser pulse duration may be a continuous wave or a pulsed laser; in some examples the laser pulse duration may occur in a microsecond range, a picosecond range, or a femtosecond range; such as about 0.1 femtoseconds to about 300 nanoseconds; such as about 1 femtosecond to about 500 picoseconds, such as about 1 femtosecond to about 150 nanoseconds, such as about 1 femtosecond to about 100 nanoseconds;
Translation speed: about 1 millimeter per second to about 2 meters per second, such as about 1 millimeter per second to about 1 meter per second
Focusing depth: about 0 microns to about 2000 microns (beneath the surface of the workpiece), such as about 0 microns to about 1000 microns (beneath the surface of the workpiece), such as about 1 micron to about 100 microns (beneath the surface of the workpiece), such as about 0 microns to about 5 microns (beneath the surface of the workpiece), such as about 0 microns to about 1 micron (beneath the surface of the workpiece).
Laser Pulse Energy: about 1 nanojoule to about 2 joules, such as about 10 nanojoules to about 200 millijoules.

The third laser source 712.3 may be configured to emit a third laser 714.3 with laser parameters sufficient to perform a laser-based subsurface damage region processing operation. In some examples, the third laser source 712.3 may be operable to emit a laser 714.3 at a third incidence angle (e.g., generally perpendicular or non-perpendicular incidence angle). The first incidence angle may be different from the second incidence angle and may be different from the third incidence angle. In some embodiments, the third laser source 712.3 may be configured to emit a third laser 714.3 in accordance with the following fine laser parameters:
Laser wavelength: about 190 nanometers to about 1100 nanometers, such as about 190 nanometers to about 300 nanometers, such as about 193 nanometers, such as about 200 nanometers, such as about 248 nanometers, such as about 266 nanometers, such as about 343 nanometers, such as about 355 nanometers, such as about 405 nanometers, such as about 532 nanometers, such as about 1064 nanometers, such as about 1080 nanometers; or multiple wavelengths (e.g., white light) including any of the foregoing;
Laser pulse frequency: continuous or about 1 kilohertz to about 20 megahertz, such as about 10 kilohertz to about 150 kilohertz, such as about 20 kilohertz to about 20 kmegahertz;
Laser power: 0.1 watts to about 500 watts, such as about 0.5 watts to about 100 watts, such as about 1 watt to about 40 watts, such as about 1 watt to about 10 watts;
Laser pulse duration: the laser pulse duration may be a continuous wave or a pulsed laser; in some examples the laser pulse duration may occur in a microsecond range, a picosecond range, or a femtosecond range; about 0.1 femtoseconds to about 300 nanoseconds; such as about 1 femtosecond to about 500 picoseconds, such as about 1 femtosecond to about 150 nanoseconds, such as about 1 femtosecond to about 100 nanoseconds;
Translation speed: about 1 millimeter per second to about 2 meters per second, such as about 1 millimeter per second to about 1 meter per second
Focusing depth: about 0 microns to about 2000 microns (beneath the surface of the workpiece), such as about 0 microns to about 1000 microns (beneath the surface of the workpiece), such as about 1 micron to about 100 microns (beneath the surface of the workpiece), such as about 0 microns to about 5 microns (beneath the surface of the workpiece), such as about 0 microns to about 1 micron (beneath the surface of the workpiece).
Laser Pulse Energy: about 1 nanojoule to about 2 joules, such as about 10 nanojoules to about 200 millijoules.

FIG. 14 depicts three laser sources 712.1, 712.2, 712.3 for purposes of illustration and discussion. Those of ordinary skill in the art, using the disclosures provided herein, will understand that the radiation-based processing system 700 may include more or fewer laser sources without deviating from the scope of the present disclosure. For instance, the radiation-based processing system 700 may include a plurality of first laser sources 712.1 operable to emit a laser 714.1 with laser parameters sufficient to perform a laser-based removal process or a laser-based surface processing operation. The radiation-based processing system 700 may include a plurality of second laser sources 712.2 operable to emit a laser 714.2 with laser parameters sufficient to perform a laser-based removal process, a laser-based treatment process, or a laser-based surface processing operation (e.g., as discussed with reference to FIGS. 6 and 12). The radiation-based processing system 700 may include a plurality of third laser sources 712.3 operable to emit a laser 714.3 with laser parameters sufficient to perform a laser-based removal process, a laser-based treatment process or a laser-based surface processing operation (e.g., as discussed with reference to FIGS. 6 and 12).

The radiation-based processing system 700 may include one or more additional laser sources to provide different functionality. In some examples, the radiation-based processing system 700 may include one or more laser sources operable to scribe a fiducial workpiece mark or ID mark on the workpiece. In some examples, the radiation-based processing system 700 may include one or more laser sources configured to singulate or cut a plurality of semiconductor die from the workpiece. In some examples, the radiation-based processing system 700 may include one or more laser sources configured to obtain metrology (e.g., surface topology measurements) of a workpiece 705. In some examples, the radiation-based processing system 700 may include one or more laser sources configured to provide a laser-based processing operation on a workpiece edge (e.g., wafer edge).

The radiation-based processing system 700 includes a workpiece support 710 configured to support a semiconductor workpiece 705 (e.g. boule and/or semiconductor wafer). The workpiece support 710 may include a chuck (e.g., vacuum chuck) or other mechanism to hold the workpiece 705 in place during laser processing according to examples of the present disclosure.

The one or more laser sources 712.1, 712.2, 712.3, . . . , 712.n may be coupled to a translation stage 720 that may move the one or more laser sources 712.1, 712.2, 712.3, . . . , 712.n relative to the workpiece. In addition, the laser sources 712.1, 712.2, 712.3, . . . , 712.n and/or translation stage 720 may include one or more optics (e.g., lens, mirrors, etc.) to facilitate moving the lasers 714.1, 714.2, 714.3, . . . , 714.n from the laser sources relative to the workpiece 705. In addition, or in the alternative, the workpiece support 710 may be operable to move the workpiece 705 relative to the one or more lasers 714.1, 714.2, 714.3, . . . , 714.n. In this way, the radiation-based processing system 700 may be able to control the translation stage 720 and/or the workpiece support 710 to impart relative motion between the lasers 714.1, 714.2, 714.3,. . . , 714.n and the workpiece 705 to implement laser-based removal processes, laser-based treatment processes, and/or laser-based surface processing operations according to examples of the present disclosure. In some examples, the translation stage 720 and/or the workpiece support 710 may be controlled to impart relative motion between the lasers 714.1, 714.2, 714.3, . . . , 714.n and the workpiece 705 to scan at least 85% of the surface through relative motion between the one or more lasers and the surface, such as at least 95% of the exposed surface, such as at least 99% of the surface to implement laser processing according to examples of the present disclosure. However, in some examples, the translation stage 720 and/or the workpiece support 710 may be controlled to scan a smaller portion of the surface of the workpiece 705 without deviating from the scope of the present disclosure. Example scanning patterns are provided in FIGS. 20-26.

For instance, in some examples, one or more lasers may scan less of the surface, such as less than about 50% of the surface. For instance, in examples involving patterning of the surface of a workpiece with areas of sub-surface damage for fiducial marking, dicing, etc., the one or more lasers may scan about 50% or less of the surface.

In some embodiments, the radiation-based processing system 700 may additionally include one or more sensors 730 for obtaining data associated with the workpiece 705, such as workpiece property data for the workpiece 705. The workpiece property data may include, for instance, data associated with a surface of the workpiece 705 (e.g., topology, roughness), subsurface regions of the workpiece 705, optical properties of the workpiece 705, temperature of the workpiece 705, doping level of the workpiece 705, polytype of the workpiece 705 (e.g., 4H, 6H), or other parameters. In some embodiments, the radiation-based processing system 700 may include adjusting an optical path of the emission of radiation 714.1, 714.2, 714.3, a frequency modulation of the emission of radiation 714.1, 714.2, 714.3 from the radiation source 712.1, 712.2, 712.3, a wavelength of the emission of radiation 714.1, 714.2, 714.3, a focus area of the emission of radiation 714.1, 714.2, 714.3 on the workpiece 705 and/or an adjustment to the power modulation of the emission of radiation 714.1, 714.2, 714.3 from the radiation source 712.1, 712.2, 712.3.

In some embodiments, the one or more sensors 730 may include, for instance, an optical sensor, such as an image capture device (e.g., camera) that may capture images at one or more wavelengths of visible light, ultraviolet light, and/or infrared light. In some embodiments, the one or more sensors 730 may include one or more surface measurement lasers that may be operable to emit a laser onto the surface or subsurface damage region of the workpiece 705 and scan the surface (based on reflections of the laser) for depth measurements, topography measurements, etc. of the surface of the workpiece 705. Other suitable sensors may be used without deviating from the scope of the present disclosure.

The radiation-based processing system 700 includes one or more control devices, such as a controller 740. The controller 740 may include one or more processors 742 and one or more memory devices 744. The one or more memory devices 744 may store computer-readable instructions that when executed by the one or more processors 742 cause the one or more processors 742 to perform one or more control functions, such as any of the functions described herein. The controller 740 may be in communication with various other aspects of the radiation-based processing system 700 through one or more wired and/or wireless control links. The controller 740 may send control signals to the various components of the radiation-based processing system 700 (e.g., the laser sources 712.1, 712.2, 712.3, . . . , 712.n, the workpiece support 710, the sensor 730) to implement a laser processing operation on the workpiece 705.

In some embodiments, the controller 740 may control aspects of the radiation-based processing system 700 (e.g., the laser sources 712.1, 712.2, 712.3, . . . , 712.n) based at least in part on data from the sensor(s) 730. For instance, the controller 740 may adjust various laser parameters for the lasers 714.1, 714.2, 714.3, . . . , 714.n emitted by the laser sources 712.1., 712.2, 712.3, . . . , 712.n based at least in part on data from the sensor(s) 730. The laser parameters may include, for instance, one or more of focusing depth, laser power, laser wavelength, laser pulse duration, laser pulse frequency, laser pulse energy, scan pattern, scan angle (e.g., relative to surface topography, such as step structures), and/or translation speed. In some embodiments, the laser parameters may include incidence angle of the lasers 714.1, 714.2, 714.3, . . . , 714.n on the workpiece 705. For instance, the controller 740 may be configured to adjust one or more of the aspects of the radiation-based processing system 700 to adjust the incidence angle of at least one of the one or more lasers 712.1, 712.2, 712.3, . . . , 712.n relative to the surface of the workpiece 705.

In some embodiments, the laser sources 712.1, 712.2, 712.3 . . . , 712.n may include an adaptive optics system that may include one or more lenses, mirrors, or other optical devices. The lenses, mirrors, or other optical devices may be moved or adjusted to adjust one or more of the one or more laser parameters. For instance, the one or more lenses may be swapped or adjusted to change a focal depth of the lasers 714.1, 714.2, 714.3 . . . , 714.n.

In some examples, the controller 740 may be configured to adjust one or more laser parameters based on sensor data associated with a current workpiece 705 undergoing a laser-based surface processing operation (e.g., dynamic adjustment during or after a laser-based surface processing operation) or based on sensor data associated with past semiconductor workpieces that had previous undergone a laser-based surface processing operation.

The aforementioned radiation-based processing system 700 that is a coherent radiation-based processing system is provided for purposes of discussion and illustration. It will be understood by one skilled in the art, using the disclosures provided herein, that any combination of coherent or incoherent radiation sources may be implemented in the radiation-based processing system 700 of FIG. 14, including one or more of a gas discharge source(s), incandescent radiation source(s), electroluminescence emitter(s), electronic or magnetic oscillator(s), free electron resonator(s), x-ray emitter(s), or bremsstrahlung emitter(s), by non-limiting example.

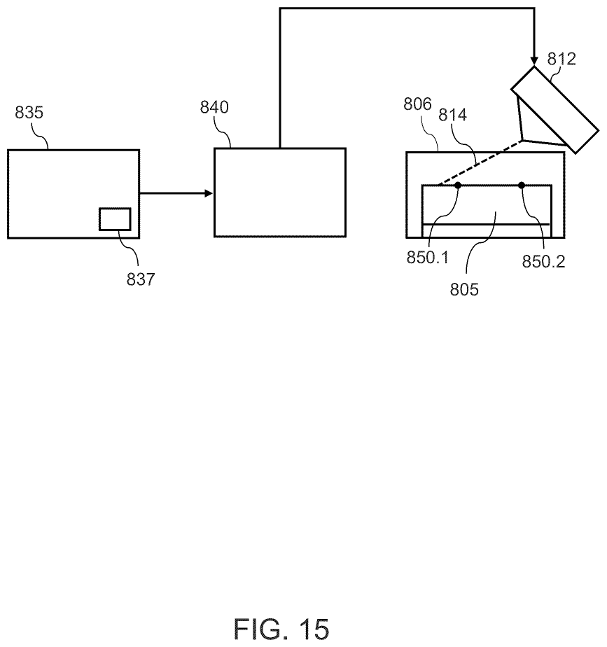

FIG. 15 depicts an overview of example control of a laser source 812 based at least in part on sensor data 835 from the one or more sensors 730 or other data (e.g., from metrology tools) according to examples of the present disclosure. As shown, the sensor data 835 may be provided to the controller 840 (e.g., through a communication link). The sensor data 835 may include, for instance, workpiece property data 837. Workpiece property data 837 may include data associated with a surface of the workpiece 805 (e.g., topology, roughness), subsurface regions of the workpiece 805, optical properties of the workpiece 805, temperature of the workpiece 805, doping level of the workpiece 805, polytype of the workpiece 805 (e.g., 4H, 6H), or other parameters. In some examples, the workpiece property data 837 may include data associated with a surface topology of the workpiece. In some examples, the workpiece property data 837 may include an image of the exposed surface obtained using an optical sensor or image capture device. In some examples, a scan of the exposed surface may be obtained using one or more surface measurement lasers or other optical devices. In some examples, an image may be captured of the exposed surface and analyzed using computer image processing techniques (e.g., classifier models, such as machine-learned classifier models) to determine data indicative of workpiece properties, such as the presence of anomalies, defects, roughness, topology, optical properties, etc. In some examples, the workpiece may be submerged in or behind a media 806 (e.g., a fluid, a gas, a window, etc.) or behind a material that alters the angle of incidence or refraction of an emission 814 of radiation from the laser source 812 in accordance with Snell's law as the emission 814 travels to the workpiece 805.

The controller 840 may determine one or more laser parameters for the emission 814 of radiation from the laser source 812 on the workpiece 805 based on the sensor data 835, such as laser incidence angle. For instance, in some embodiments, the controller 840 may access a model, algorithm, function, lookup table, machine-learned model, etc., that correlates one or more laser parameters based on the data and/or position on the workpiece 805 or a media 806 (e.g., a fluid, a gas, a window, etc.) between the radiation source 812 and the workpiece 805.

In some embodiments, the one or more laser parameters are specified as a function of both a position on the workpiece 805 and sensor data 835 or other data associated with that specific position. In some examples, the controller 840 may determine an incidence angle based on a refractive index of the media 806 (e.g., a fluid, a gas, a window, etc.) between the radiation source 812 and the workpiece 805. For instance, the controller 840 may determine a first incidence angle for the laser emission 814 for ablating or removing material at a first position 850.1 on the workpiece 805. The controller 840 may determine a second incidence angle for the emission 814 from the laser source 812 for ablating or removing material at a second position 850.2 on the workpiece 805. The first incidence angle may be different from or the same as the second incidence angle.

In some examples, the laser source 812 may be dynamically adjusted, or tuned, during a laser surface processing operation. The one or more sensors 830 may provide sensor data 835 to the controller 840 and the controller 840 may determine, or adjust, one or more laser parameters for the laser emission 814 based on the sensor data 835 while performing the laser surface processing operation. For instance, the one or more sensors 830 may provide a surface topography of the workpiece 805 to the controller 840 while the laser emission 814 is processing the surface of the workpiece 805. The controller 840 may then adjust one or more laser parameters of the laser emission 814 based on the data while the laser emission 814 is still processing the surface of the workpiece 805. In this way, the one or more laser parameters may be dynamically adjusted, or tuned, during laser surface processing operations.

In some examples, the one or more laser parameters of the laser source 812 may be adaptively tuned, or adjusted, through multiple laser surface processing operations. The one or more sensors 830 may aggregate data regarding the workpiece 805 before, during, and after a laser surface processing operation and provide it to the controller 840. The controller 840 may then tune one or more laser parameters of the laser source 812 based on the aggregated data from the one or more sensors 830. For instance, the laser source 812 may include a set of one or more laser parameters for a laser surface processing operation. The laser source 812 may perform a laser surface processing operation on the surface of a workpiece 805 and the one or more sensors 830 may obtain data regarding the surface of the workpiece 805 after the operation. The data regarding the surface of the workpiece 805 may then be provided to the controller 840 which may adjust, or tune, one or more of the set laser parameters associated with the laser source 812 and reprocess the surface of the workpiece 805. In some examples, the one or more laser parameters may be adaptively tuned for future laser surface processing operations and/or future additional workpiece(s) 805. For instance, the controller 840 may determine one or more laser parameter adjustments based on one or more laser surface processing operations on a first workpiece 805 and apply the adjustments to one or more laser parameters for a laser surface processing operation on a second workpiece 805.

The controller 840 of FIG. 15 is discussed with reference to a laser source 812, however, the controller 840 may additionally alter parameters of other radiation sources (not pictured) than the laser source 812 that provide an emission of radiation for processing a workpiece 805. The other radiation sources may include one or more of a gas discharge source(s), incandescent radiation source(s), electroluminescence emitter(s), electronic or magnetic oscillator(s), free electron resonator(s), x-ray emitter(s), or bremsstrahlung emitter(s), by non-limiting example.

FIG. 16 depicts an array of radiation sources 910.1, 910.2, . . . , 910.n providing emission of radiation 912.1, 912.2, . . . , 912.n onto a surface 902 of a semiconductor workpiece 900 (e.g., silicon carbide semiconductor wafer) according to examples of the present disclosure. The radiation sources 910.1, 910.2, . . . , 910.n may each be configured to respectively provide emissions 912.1, 912.2, . . . , 912.n in accordance with various parameters. The parameters may include, for instance, focusing depth, power, wavelength, pulse duration, pulse frequency, pulse energy, scan pattern, incidence angle, etc. The radiation sources 910.1, 910.2, . . . , 910.n may each be the same type of radiation source (as pictured) or different types of radiation sources (not pictured). The radiation sources 910.1, 910.2, . . . , 910.n may be configured to provide the emissions 912.1, 912.2, . . . , 912.n in accordance with the same laser parameters or different laser parameters.

The radiation sources 910.1, 910.2, . . . , 910.n may be collectively controlled or independently controlled to implement a scan pattern 920 on the surface 902 of the semiconductor workpiece 900 to implement a subsurface processing operation according to examples of the present disclosure. For instance, each of the radiation sources 910.1, 910.2, . . . , 910.n may be collectively controlled as a group or independently controlled relative to one another to provide an individual scan 922.1, 922.2, . . . , 922.n to provide a scan pattern 920 on the surface 902 of the semiconductor workpiece 900.

Each of the radiation sources 910.1, 910.2, . . . , 910.n may be individually controlled to provide the emissions 912.1, 912.2, . . . , 912.n at different incidence angles (e.g., perpendicular or non-perpendicular incidence angles) relative to one another. For instance, radiation source 910.1 may provide the emission 912.1 at a first non-perpendicular incidence angle θ₁. The radiation source 910.2 may provide the emission 912.2 at a perpendicular incidence angle. The radiation source 910.n may provide the emission 912.n at a second non-perpendicular incidence angle θ₂ and from a different direction relative to the radiation source 910.1.

FIG. 16 depicts the three radiation sources 910.1, 910.2, . . . , 910.n for purposes of illustration and discussion. Those of ordinary skill in the art, using the disclosures provided herein, will understand that the system may include more or fewer laser sources without deviating from the scope of the present disclosure. The three radiation sources 910.1, 910.2, . . . , 910.n of FIG. 16 may also include other radiation sources, such as one or more of a gas discharge source(s), incandescent radiation source(s), electroluminescence emitter(s), electronic or magnetic oscillator(s), free electron resonator(s), x-ray emitter(s), or bremsstrahlung emitter(s), by non-limiting example.

FIG. 17 depicts a cross-sectional view of a testing apparatus 1000 for determining fracture strength. FIG. 18 depicts a plan view of a testing apparatus 1000 for determining fracture strength. As illustrated, a semiconductor workpiece 1020 (e.g., silicon carbide semiconductor wafer) is placed on a two rectangular workpiece supports 1010, 1012 that are spaced apart a distance D. The distance D is 4 inches for an approximately 150 mm diameter semiconductor workpiece and a gap of 6 inches for an approximately 200 mm diameter semiconductor workpiece. In some examples the distance D may be greater in the event the diameter of the workpiece 1020 is greater. In some examples, the distance D may be less in the event the diameter of the wafer is less. In some examples, a ratio of the distance D to the diameter is approximately 0.5 to about 0.8, such as about 0.7. In some examples, the rectangular workpiece supports 1010, 1012 may each have a width W1. The width W1 may be 1 inch.

The testing apparatus 1000 includes a test head 1022. The test head 1022 may have a rounded tip for contact with the semiconductor workpiece 1020 during performance of the test.

The test head 1022 may be driven in a direction towards and against the semiconductor workpiece 1020 by an actuator 1023. In some examples, the actuator 1023 may be, for instance, a ball screw. However, other suitable actuators (e.g., linear actuators) may be used without deviating from the scope of the present disclosure. The distance the test head 1022 is driven may be measured by an encoder or other suitable sensor that may provide data indicative of the distance the test head 1022 is driven. The testing apparatus 1000 may include a load cell sensor or other suitable sensor configured to measure force applied to the semiconductor workpiece 1020 during a fracture strength test.

The testing apparatus 1000 may implement a fracture strength test by driving the test head 1022 against the semiconductor workpiece 1020 along an axis 1025 that is halfway between the workpiece support 1010, 1012 such that the test head 1022 is applied to a center portion of the semiconductor workpiece 1020. The distance the test head 1022 is driven may be measured. The displacement of the semiconductor workpiece 1020 may be measured during the fracture strength test. The force applied to the semiconductor workpiece 1020 with the test head 1022 may be measured during the fracture strength test. The fracture strength, as used herein, refers to the force that may be applied to the semiconductor workpiece 1020 before breaking the semiconductor workpiece 1020 during a fracture strength test with the testing system of FIGS. 17 and 18. The magnitude of the force (in Newtons or other suitable unit of force) may be the fracture strength.

In some embodiments, the treatment process may improve the fracture strength of the semiconductor workpiece 1020 tested in the manner outlined above, providing a fracture strength in a range of about 17.5 Newtons or greater, such as about 25 Newtons to about 75 Newtons.

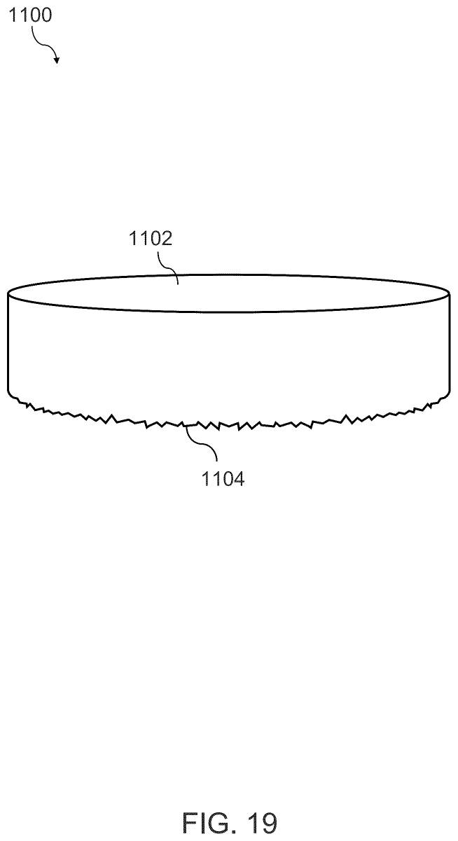

FIG. 19 depicts a semiconductor wafer 1100 (e.g., the first portion 118 separated from the semiconductor workpiece 115 of FIG. 6) with a first major surface 1102 and a second major surface 1104. According to aspects of the present disclosure, the treatment process may reduce the surface roughness of a semiconductor wafer 1100 after a separation process is performed. In some examples, additional processing may be performed on the first major surface 1102 or the second major surface 1104 to further reduce the surface roughness. In some embodiments, the first major surface 1102 may have additional processing procedures performed that produce a post-processed surface roughness in a range of about 0.5 nanometers to about 180 nanometers. The second major surface 1102 of the semiconductor wafer 1100 may have a damage region fractured surface roughness in a range of about 10 microns to about 100 microns microns or greater. According to aspects of the present disclosure, as a result of the treatment process, the semiconductor wafer 1100 may have an increase in a fracture strength in a range of about 17.5 Newtons or greater relative to a semiconductor wafer produced by induced damage separation processes.

FIGS. 20-26 depict example scan patterns for a laser-based processing operation according to examples of the present disclosure. According to aspects of the present disclosure, the one or more lasers may scan the surface of a workpiece in any suitable pattern. FIG. 20 depicts an example scan pattern 1304 on an example semiconductor workpiece 1300 (e.g., silicon carbide semiconductor workpiece) according to example embodiments of the present disclosure. The scan pattern depicted in FIG. 20 comprises a plurality of parallel scans or passes in a direction generally perpendicular to, for instance, a flat 1302 of the semiconductor workpiece 1300.

FIG. 21 depicts an example scan pattern 1306 on an example semiconductor workpiece 1300 (e.g., silicon carbide semiconductor workpiece) according to example embodiments of the present disclosure. The scan pattern 1306 depicted in FIG. 21 comprises a spiral scan pattern on a surface of the semiconductor workpiece 1300.

FIG. 22 depicts an example scan pattern 1308 on an example semiconductor workpiece 1300 (e.g., silicon carbide semiconductor workpiece) according to example embodiments of the present disclosure. The scan pattern 1308 depicted in FIG. 22 comprises a plurality of generally parallel scans or passes in a direction that is angled (not generally perpendicular and not generally parallel) to, for instance, a flat 1302 of the semiconductor workpiece 1300.

FIG. 23 depicts an example scan pattern 1310 on an example semiconductor workpiece 1300 (e.g., silicon carbide semiconductor workpiece) according to example embodiments of the present disclosure. The scan pattern 1310 depicted in FIG. 23 comprises a plurality of generally parallel scans or passes in a direction that is generally parallel to, for instance, a flat 1302 of the semiconductor workpiece 1300.

FIG. 24 depicts an example scan pattern 1312 on an example semiconductor workpiece 1300 (e.g., silicon carbide semiconductor workpiece) according to example embodiments of the present disclosure. The scan pattern 1312 depicted in FIG. 24 comprises a plurality of generally parallel scans or passes and a plurality of generally perpendicular scans or passes to, for instance, a flat 1302 of the semiconductor workpiece 1300.

Other suitable laser scan patterns may be used without deviating from the scope of the present disclosure. For instance, the laser scan pattern may be an irregular or a random scan pattern. As additional non-limiting examples, the laser scan pattern may be a spot pattern, non-continuous pattern, zig zag pattern, herringbone pattern, chevron pattern, array of polygons, concentric circles, or other suitable pattern. In some examples, the workpiece may be rotated while the one or more lasers are implementing the laser scan pattern. In some examples, a density of laser scan lines for a first portion of the semiconductor workpiece may be different from a density of laser lines for a second portion of the semiconductor workpiece. For instance, the density of laser scans may be higher on portions of the semiconductor workpiece with increased surface roughness relative to other portions of the semiconductor workpiece.

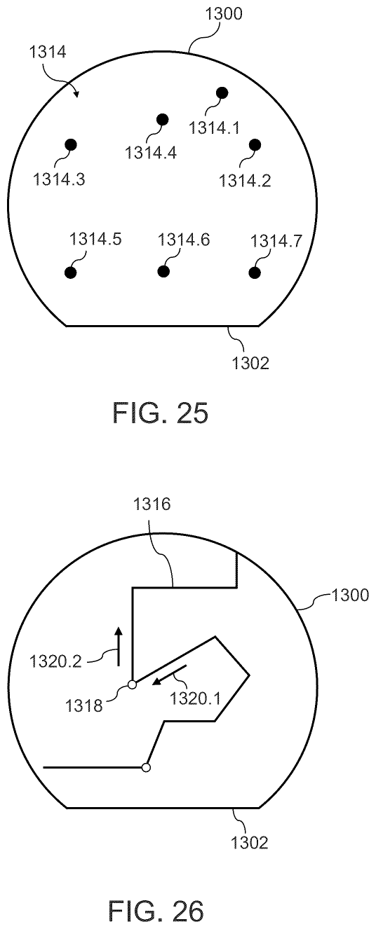

For instance, FIG. 25 depicts an example non-continuous scan pattern 1314 on an example semiconductor workpiece 1300 (e.g., silicon carbide semiconductor wafer) according to example embodiments of the present disclosure. The scan pattern 1314 depicted in FIG. 21 includes a plurality of discrete and separated scan points 1314.1, 1314.2, . . . , 1314.n on the semiconductor workpiece 1300. For instance, workpiece property data (e.g., sensor data associated with one or more workpiece properties) may indicate the presence of local peak topographical areas on the semiconductor workpiece 1300. The laser scan pattern 1314 can provide emission of the laser on the discrete points 1314.1, 1314.2, . . . , 1314.n to remove the local peak topographical areas. The discrete points can be in a regular pattern or in a scattered, irregular pattern.

In some embodiments, the scan pattern and/or scan angle (e.g., scan angle φ) may be adjusted (e.g., while scanning the semiconductor workpiece) based on data, such as sensor data associated with one or more workpiece properties. For instance, FIG. 26 depicts an example scan pattern 1316 on an example semiconductor workpiece 1300 (e.g., silicon carbide semiconductor wafer) according to example embodiments of the present disclosure. The scan pattern 1316 has been adjusted, for instance, at point 1318 from a first direction 1320.1 to a second direction 1320.2. In some embodiments, the scan pattern 1316 may be adjusted, for instance, based on data associated with one or more workpiece properties. For instance, the scan pattern 1316 may change directions to address high surface topographical areas (e.g., peaks) or other features on the surface of the semiconductor workpiece 1300. The scan pattern 1316 may be adjusted based on other factors without deviating from the scope of the present disclosure.

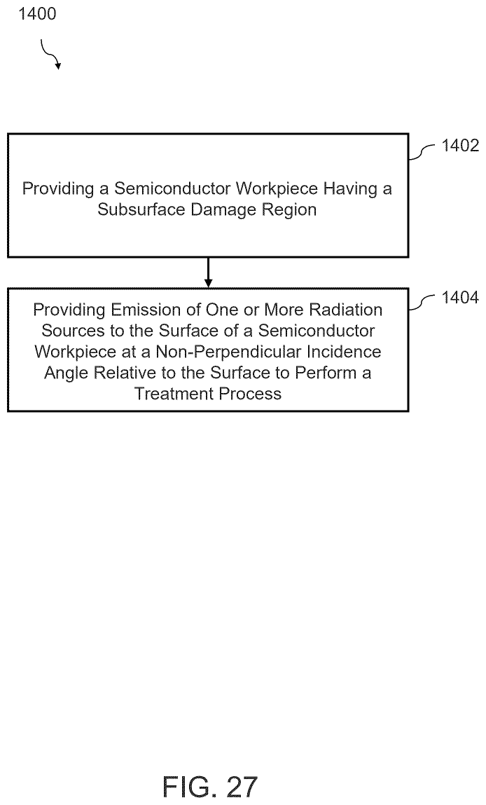

FIG. 27 depicts a flow chart diagram of an example method 1400 according to aspects of the present disclosure. FIG. 27 is intended to represent structures for identification and description and is not intended to represent the structures to physical scale. The method 1400 depicts operations in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

At 1402, the method 1400 includes providing a semiconductor workpiece having a subsurface damage region. The semiconductor workpiece may be a semiconductor wafer or a boule. Additionally, the semiconductor workpiece may be made of a variety of materials. For instance, the semiconductor workpiece may include silicon carbide, such as an off-axis 4H silicon carbide crystalline material. In some examples, providing the semiconductor workpiece may include separating the semiconductor workpiece from a boule using a removal process (e.g., laser-based removal process or wire saw-based removal process). In some examples, the subsurface damage region may be induced through laser-based processes or ion implantation.

At 1404, the method 1400 includes providing emission of one or more radiation sources to the surface of a semiconductor workpiece. In some examples, the emission of one or more radiation sources may be a laser-based emission, which may be provided at a non-perpendicular incidence angle relative to the surface. The non-perpendicular incidence angle may be any acute angle relative to the surface, such as 75° or less, such as 45°, such as 30°, such as 15°. The one or more lasers may be emitted through one or more optics (e.g., lenses, mirrors, etc.) to process the surface of the semiconductor workpiece.

In some examples, the emission of the radiation source may also include other radiation sources, such as one or more of a gas discharge source(s), incandescent radiation source(s), electroluminescence emitter(s), electronic or magnetic oscillator(s), free electron resonator(s), x-ray emitter(s), or bremsstrahlung emitter(s), by non-limiting example. In some examples, the emission of radiation from another radiation source may be provided to the surface at any angle, such as an angle between 0° and 90°.

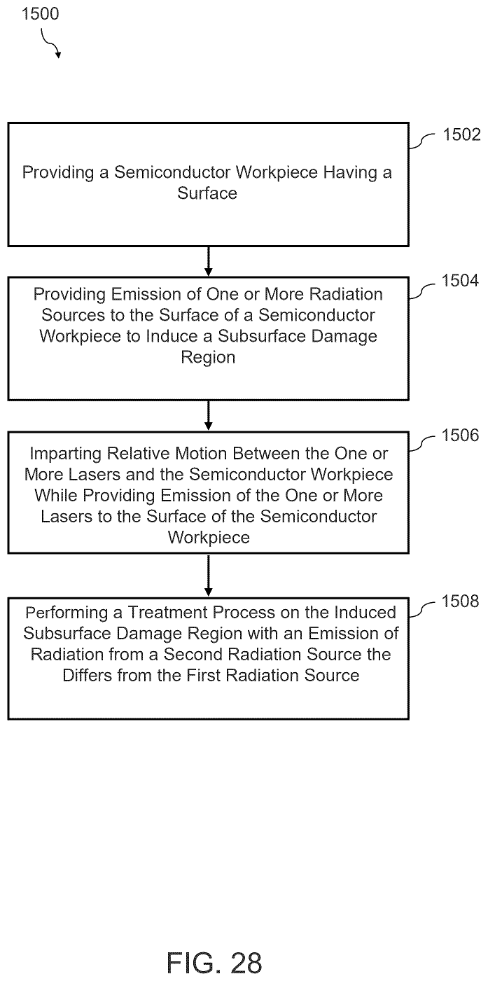

FIG. 28 depicts a flow chart diagram of an example method 1500 according to aspects of the present disclosure. The method 1500 depicts operations in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

At 1502, the method 1500 includes providing a semiconductor workpiece having a surface. The semiconductor workpiece may be a semiconductor wafer or a boule. Additionally, the semiconductor workpiece may be made of a variety of materials. For instance, the semiconductor workpiece may include silicon carbide, such as an off-axis 4H silicon carbide crystalline material. In some examples, providing the semiconductor workpiece may include separating the semiconductor workpiece from a boule using a removal process (e.g., laser-based removal process or wire saw-based removal process).

At 1504, the method 1500 includes providing emission of one or more radiation sources (e.g., a laser) to the surface of a semiconductor workpiece to induce a subsurface damage region in the semiconductor workpiece.

At 1506, the method 1500 includes imparting relative motion between the one or more radiation sources configured to induce a subsurface damage region and the semiconductor workpiece while providing emission of the one or more radiation sources to the surface of the workpiece. Imparting relative motion may be performed in a variety of ways. For example, imparting relative motion may include adjusting one or more optics or rotating the semiconductor workpiece. Additionally, in some examples, imparting relative motion may include adjusting the non-perpendicular incidence angle of the one or more radiation sources.

At 1508, the method 1500 includes providing emission of one or more radiation sources that differ in type from the radiation source of 1502, 1504, and 1506 to the surface of a semiconductor workpiece. In some examples, the emission of the radiation source may also include one or more of a gas discharge source(s), incandescent radiation source(s), electroluminescence emitter(s), electronic or magnetic oscillator(s), free electron resonator(s), x-ray emitter(s), or bremsstrahlung emitter(s), by non-limiting example. In some examples, the emission of radiation from another radiation source may be provided to the surface at any angle, such as an angle between 020 and 90°.

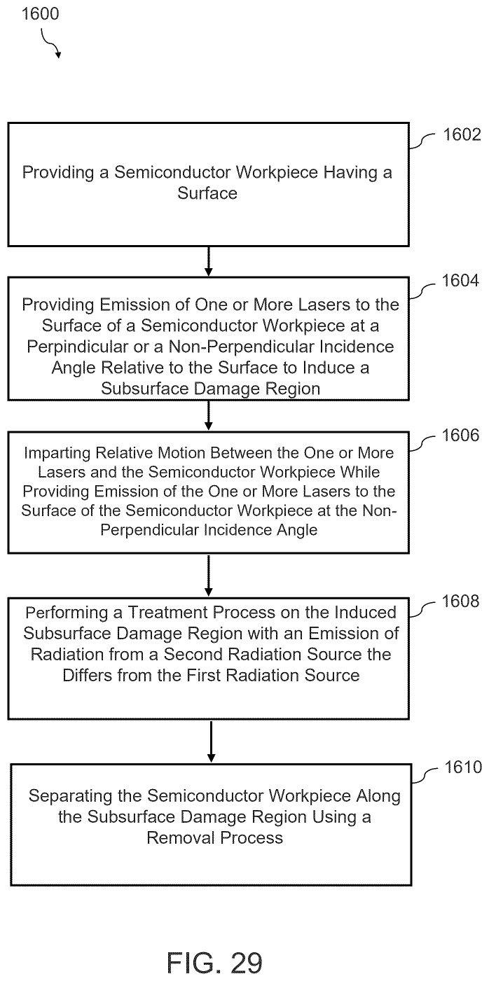

FIG. 29 depicts a flow chart diagram of an example method 1600 according to aspects of the present disclosure. The method 1600 depicts operations in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

At 1602, the method 1600 includes providing a semiconductor workpiece having a surface. The semiconductor workpiece may be a semiconductor wafer or a boule. Additionally, the semiconductor workpiece may be made of a variety of materials. For instance, the semiconductor workpiece may include silicon carbide, such as an off-axis 4H silicon carbide crystalline material. In some examples, providing the semiconductor workpiece may include separating the semiconductor workpiece from a boule using a removal process (e.g., laser-based removal process).

At 1604, the method 1600 includes providing emission of one or more radiation sources to the surface of a semiconductor workpiece at a perpendicular or a non-perpendicular incidence angle relative to the surface. The non-perpendicular incidence angle may be any acute angle relative to the surface, such as 75° or less, such as 45°, such as 30°, such as 15°. The one or more radiation sources may be emitted through one or more optics (e.g., lenses, mirrors, etc.) to process the surface of the semiconductor workpiece.

At 1606, the method includes imparting relative motion between the one or more lasers and the semiconductor workpiece while providing emission of the one or more radiation sources to the surface of the semiconductor workpiece at the non-perpendicular incidence angle. Imparting relative motion may be performed in a variety of ways. For example, imparting relative motion may include adjusting one or more optics or rotating the semiconductor workpiece. Additionally, in some examples, imparting relative motion may include adjusting the non-perpendicular incidence angle of the one or more radiation sources. The non-perpendicular incidence angle may be adjusted based on a variety of factors. For example, the non-perpendicular incidence angle may be adjusted based on a number of scans of the one or more radiation sources, a surface roughness of the surface, and/or a subsurface damage depth of the semiconductor workpiece.

In some examples, the scan angle (e.g., scan angle φ of FIG. 8) may be adjusted (e.g., during scanning of the workpiece) based on one or more workpiece properties and/or surface topography of the workpiece. For instance, the scan angle may be adjusted to remain generally perpendicular to a length of one or more trenches or other features in the workpiece.

At 1608 the method 1600 includes providing emission of one or more radiation sources to the surface of a semiconductor workpiece to perform a treatment process on the induced subsurface damage region of the semiconductor workpiece. In some examples, the emission of the radiation source may also include one or more of a laser-based radiation source(s), gas discharge source(s), incandescent radiation source(s), electroluminescence emitter(s), electronic or magnetic oscillator(s), free electron resonator(s), x-ray emitter(s), or bremsstrahlung emitter(s), by non-limiting example. In some examples, the emission of radiation from another radiation source may be provided to the surface at any angle, such as an angle between 0° and 90°. In some examples, the non-perpendicular incidence angle may be any acute angle relative to the surface, such as 75° or less, such as 45°, such as 30°, such as 15°.

At 1610, the method 1600 includes separating the semiconductor workpiece along the subsurface damage region. As a result of the treatment process at 1608, the newly exposed surfaces of the first portion and the second portion of the semiconductor workpiece may exhibit reduced surface roughness as a result of the treatment process. For instance, the first portion of the semiconductor workpiece and the second portion of the semiconductor workpiece may have the newly exposed surface with a surface roughness less than about 10 microns to less than about 100 microns. Additionally, the treatment process may improve the fracture strength of the first and/or the second portions of the semiconductor workpiece, providing a fracture strength in a range of about 17.5 Newtons or greater, such as about 25 Newtons to about 75 Newtons.

Example aspects of the present disclosure are set forth below. Any of the below features or examples may be used in combination with any of the embodiments or features provided in the present disclosure.

In an aspect, the present disclosure provides an example method. In some implementations, the example method includes providing a semiconductor workpiece having a subsurface damage region. In some implementations, the example method includes performing a treatment process on the subsurface damage region. In some implementations, the treatment process includes providing a treatment emission of radiation from a radiation source to the subsurface damage region of the semiconductor workpiece at a non-perpendicular angle relative to the subsurface damage region.

In some implementations of the example method, the radiation source includes one or more laser sources that provide the treatment emission of the radiation to the subsurface damage region of a semiconductor workpiece.

In some implementations of the example method, the radiation source includes one or more gas discharge sources that provide the treatment emission of the radiation to the subsurface damage region of a semiconductor workpiece.

In some implementations of the example method, the radiation source includes one or more incandescent radiation sources that provide the treatment emission of the radiation to the subsurface damage region of a semiconductor workpiece.

In some implementations of the example method, the radiation source includes one or more electroluminescence emitters that provide the treatment emission of the radiation to the subsurface damage region of a semiconductor workpiece.

In some implementations of the example method, the radiation source includes one or more electronic or magnetic oscillators that provide the treatment emission of the radiation to the subsurface damage region of a semiconductor workpiece.

In some implementations of the example method, the radiation source includes one or more free electron resonators that provide the treatment emission of the radiation to the subsurface damage region of a semiconductor workpiece.

In some implementations of the example method, the radiation source includes one or more x-ray emitters that provide the treatment emission of the radiation to the subsurface damage region of a semiconductor workpiece.

In some implementations of the example method, the radiation source includes one or more bremsstrahlung emitters that provide the treatment emission of the radiation to the subsurface damage region of a semiconductor workpiece.

In some implementations of the example method, the treatment process includes providing the treatment emission of radiation at the non-perpendicular angle of about 75° or less.

In some implementations of the example method, the treatment process includes providing the treatment emission of radiation at the non-perpendicular angle of about 30° or less.

In some implementations of the example method, the treatment process includes providing the treatment emission of radiation at the non-perpendicular angle of about 15° or less.

In some implementations of the example method, the treatment process includes providing the treatment emission of radiation at a plurality of incidence angles.

In some implementations of the example method, the method includes separating a semiconductor wafer from the semiconductor workpiece after the treatment process using a removal process.

In some implementations of the example method, the treatment process reduces a surface roughness Sz of at least one major surface of the semiconductor wafer after separation.

In some implementations of the example method, at least one major surface of the semiconductor wafer has a surface roughness of about 10 to about 100 microns.

In some implementations of the example method, at least one major surface of the semiconductor wafer has a surface roughness in a range of about 0.5 nanometer to about 350 nanometers.

In some implementations of the example method, providing the treatment emission of the radiation to the subsurface damage region of the semiconductor workpiece increases a fracture strength of the semiconductor wafer.

In some implementations of the example method, the treatment process provides the fracture strength of the semiconductor wafer in a range of about 17.5 Newtons or greater.

In some implementations of the example method, the treatment process provides a fracture strength in a range of about 25 Newtons to about 75 Newtons.

In some implementations of the example method, the fracture strength is determined by placing the semiconductor wafer on two support structures and providing a force on the semiconductor wafer at a location halfway between the two support structures, wherein the fracture strength corresponds to a greatest force provided to the semiconductor wafer without breaking.

In some implementations of the example method, the method includes performing a surface processing operation on the semiconductor workpiece, wherein implementing the treatment process is performed prior to performing the surface processing operation.

In some implementations, the example method includes obtaining data indicative of a workpiece property, wherein the method includes adjusting the non-perpendicular angle of the treatment emission of radiation from the radiation source based on the data indicative of the workpiece property.

In some implementations, the example method includes obtaining data indicative of a workpiece property, wherein the method includes adjusting an optical path of the treatment emission of the radiation from the radiation source based on the data indicative of the workpiece property.

In some implementations, the example method includes obtaining data indicative of a workpiece property, wherein the method includes adjusting a frequency modulation of the treatment emission of radiation from the radiation source based on the data indicative of the workpiece property.

In some implementations, the example method includes obtaining data indicative of a workpiece property, wherein the method includes adjusting wavelength of the treatment emission of radiation from the radiation source based on the data indicative of the workpiece property.

In some implementations, the example method includes obtaining data indicative of a workpiece property, wherein the method includes adjusting a focus area of the treatment emission of the radiation from the radiation source based on the data indicative of the workpiece property.

In some implementations, the example method includes obtaining data indicative of a workpiece property, wherein the method includes adjusting a power modulation of the treatment emission of the radiation from the radiation source based on the data indicative of the workpiece property.

In some implementations of the example method, the method includes adjusting a scan angle of the treatment emission of the radiation source relative to one or more features of the subsurface damage region of the semiconductor workpiece.

In some implementations of the example method, the semiconductor workpiece is a silicon carbide boule.

In some implementations of the example method, the method involves imparting relative motion between the radiation source and the semiconductor workpiece.

In some implementations of the example method, imparting relative motion between the radiation source and the semiconductor workpiece includes adjusting one or more parameters of the treatment emission of the radiation source while imparting relative motion.

In some implementations of the example method, the subsurface damage region is a laser-based damage region in the semiconductor workpiece.

In some implementations of the example method, the subsurface damage region is an ion implantation damage region in the semiconductor workpiece.

In an aspect, the present disclosure provides an example method. In some implementations, the example method includes providing a semiconductor workpiece. In some implementations, the example method includes inducing a subsurface damage region with a damage-inducing emission of radiation from a first radiation source. In some implementations, the example method includes performing a treatment process on the subsurface damage region with a treatment emission of radiation from a second radiation source. In some implementations, the damage-inducing emission of radiation from the first radiation source differs from the treatment emission of radiation from the second radiation source.

In some implementations of the example method, the second radiation source provides the treatment emission at a non-perpendicular angle relative to the subsurface damage region.

In some implementations of the example method, the non-perpendicular angle includes an angle of about 75° or less.

In some implementations of the example method, the non-perpendicular angle includes an angle of about 30° or less.

In some implementations of the example method, the non-perpendicular angle includes an angle of about 15° or less.

In some implementations of the example method, the treatment process includes providing the treatment emission of radiation at a plurality of incidence angles.

In some implementations of the example method, the first radiation source includes one or more laser sources that provide the damage-inducing emission of radiation to a subsurface region of a semiconductor workpiece.

In some implementations of the example method, the second radiation source includes one or more gas discharge sources that provide the treatment emission of radiation to the subsurface damage region of a semiconductor workpiece.

In some implementations of the example method, the second radiation source includes one or more incandescent radiation sources that provide the treatment emission of radiation to the subsurface damage region of a semiconductor workpiece.

In some implementations of the example method, the second radiation source includes one or more electroluminescence emitters that provide the treatment emission of radiation to the subsurface damage region of a semiconductor workpiece.

In some implementations of the example method, the second radiation source includes one or more electronic or magnetic oscillators that provide the treatment emission of radiation to the subsurface damage region of a semiconductor workpiece.

In some implementations of the example method, the second radiation source includes one or more free electron resonators that provide the treatment emission of radiation to the subsurface damage region of a semiconductor workpiece.

In some implementations of the example method, the second radiation source includes one or more x-ray emitters that provide the treatment emission of radiation to the subsurface damage region of a semiconductor workpiece.

In some implementations of the example method, the second radiation source includes one or more bremsstrahlung emitters that provide the treatment emission of radiation to the subsurface damage region of a semiconductor workpiece.

In some implementations of the example method, the method further comprises separating the semiconductor workpiece along the subsurface damage region using a removal process to produce a semiconductor wafer comprising a first major surface and a second major surface.

In some implementations of the example method, the treatment process reduces a surface roughness Sz of at least one major surface of the semiconductor wafer after separation.

In some implementations of the example method, at least one major surface of the semiconductor wafer has a surface roughness of about 10 microns to about 100 microns or greater.

In some implementations of the example method, at least one major surface of the semiconductor wafer has a surface roughness in a range of about 0.5 nanometer to about 180 nanometers.

In some implementations of the example method, providing the treatment emission of radiation to the subsurface damage region of the semiconductor workpiece increases a fracture strength of the semiconductor wafer.

In some implementations of the example method, the treatment process provides the fracture strength of the semiconductor wafer in a range of about 17.5 Newtons or greater.

In some implementations of the example method, the treatment process provides a fracture strength in a range of about 25 Newtons to about 75 Newtons.

In some implementations of the example method, the fracture strength is determined by placing the semiconductor wafer on two support structures and providing a force on the semiconductor wafer at a location halfway between the two support structures, wherein the fracture strength corresponds to a greatest force provided to the semiconductor wafer without breaking.

In some implementations of the example method, the method includes performing a surface processing operation on the semiconductor workpiece, wherein implementing the treatment process is performed prior to performing the surface processing operation.

In some implementations, the example method includes obtaining data indicative of a workpiece property, wherein the method includes adjusting a non-perpendicular angle of the treatment emission of radiation from the second radiation source based on the data indicative of the workpiece property.

In some implementations of the example method, the method includes adjusting a scan angle of the treatment emission of the second radiation source relative to one or more features of the subsurface damage region of the semiconductor workpiece.

In some implementations of the example method, the semiconductor workpiece is a silicon carbide boule.

In some implementations of the example method, the method involves imparting relative motion between the first radiation source or the second radiation source and the semiconductor workpiece.

In some implementations of the example method, imparting relative motion between the second radiation source and the semiconductor workpiece includes adjusting a non-perpendicular angle of the treatment emission of radiation from the second radiation source while imparting relative motion.

In an aspect, the present disclosure provides an example system. In some implementations, the example system includes a first radiation source configured to provide a damage-inducing emission, wherein the damage-inducing emission is configured to induce a subsurface damage region in the semiconductor workpiece. In some implementations, the example system includes a second radiation source configured to provide a treatment emission, wherein the treatment emission is configured to perform a treatment process on the subsurface damage region of the semiconductor workpiece. In some implementations, the example system includes at least one translation stage operable to impart relative motion between the subsurface damage region of the semiconductor workpiece and the radiation source.

In some implementations of the example system, the damage-inducing emission of radiation from the first radiation source differs from the treatment emission of radiation from the second radiation source.

In some implementations of the example system, the system further includes a controller, wherein the controller is configured to adjust one or more of the radiation source, the translation stage, or one or more optics to adjust a parameter of the emission of the radiation source relative to the subsurface damage region of the semiconductor workpiece.

In some implementations, the example system includes a sensor configured to obtain sensor data indicative of a workpiece property. In some implementations, the controller is configured to adjust a radiation parameter of the emission of the radiation source based at least in part on the sensor data.

In some implementations of the example system, the sensor is an optical sensor, a surface measurement laser, or an image capture device.

In some implementations of the example system, the controller is configured to adjust one or more radiation parameters based at least in part on the sensor data.

In some implementations of the example system, the one or more radiation parameters comprise one or more of power, pulse frequency, wavelength, pulse duration, focusing depth, pulse energy, scan pattern, scan angle, or translation speed.

In some implementations of the example system, the controller is configured to adjust an angle of incidence of the treatment emission of radiation, such that the treatment emission of radiation is provided at a non-perpendicular angle as a function of position of the subsurface damage region of the semiconductor workpiece.

In some implementations of the example system, the semiconductor workpiece is a silicon carbide boule.

In an aspect, the present disclosure provides an example semiconductor wafer. The semiconductor wafer has a first major surface and a second major surface. The first major surface has a post-processed surface roughness Sz in a range of about 0.5 nanometers to about 180 nanometers and the second major surface of the semiconductor wafer has a fractured surface roughness Sz of about 10 microns to about 100 microns. The semiconductor wafer has a fracture strength in a range of about 17.5 Newtons or greater.

In some implementations of the example semiconductor wafer, the fracture strength of the semiconductor wafer is in a range of about 25 Newtons to about 75 Newtons.

In some implementations of the example semiconductor wafer, the fracture strength is determined by placing the semiconductor wafer on two support structures and providing a force on the semiconductor wafer at a location halfway between the two support structures, wherein the fracture strength corresponds to a greatest force provided to the semiconductor wafer without breaking.

In some implementations of the example semiconductor wafer, the semiconductor wafer is a silicon carbide semiconductor wafer.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method for processing a semiconductor workpiece comprising:
providing a semiconductor workpiece having a subsurface damage region;
performing a treatment process on the subsurface damage region; and
wherein the treatment process comprises providing a treatment emission of radiation from a radiation source to the subsurface damage region of the semiconductor workpiece at a non-perpendicular angle relative to the subsurface damage region.

2. The method of claim 1, wherein the radiation source comprises one or more laser sources that provide the treatment emission of the radiation to the subsurface damage region of a semiconductor workpiece.

3. The method of claim 1, wherein the radiation source comprises one or more gas discharge sources, one or more incandescent radiation sources one or more electroluminescence emitters, one or more electronic or magnetic oscillators, one or more free electron resonators, one or more x-ray emitters, or one or more bremsstrahlung emitters.

4. The method of claim 1, wherein the treatment process comprises providing the treatment emission of radiation at the non-perpendicular angle of about 75° or less.

5. The method of claim 1, wherein the treatment process comprises providing the treatment emission of radiation at a plurality of incidence angles.

6. The method of claim 1, wherein the method comprises separating a semiconductor wafer from the semiconductor workpiece after the treatment process using a removal process.

7. The method of claim 6, wherein the treatment process provides a fracture strength of the semiconductor wafer in a range of about 17.5 Newtons or greater.

8. The method of claim 7, wherein the treatment process provides a fracture strength of the semiconductor wafer in a range of about 25 Newtons to about 75 Newtons.

9. The method of claim 7, wherein the fracture strength is determined by placing the semiconductor wafer on two support structures and providing a force on the semiconductor wafer at a location halfway between the two support structures, wherein the fracture strength corresponds to a greatest force provided to the semiconductor wafer without breaking.

10. The method of claim 1, wherein the method comprises performing a surface processing operation on the semiconductor workpiece, wherein implementing the treatment process is performed prior to performing the surface processing operation.

11. The method of claim 1, comprising obtaining data indicative of a workpiece property, wherein the method comprises adjusting the non-perpendicular angle of the treatment emission of radiation from the radiation source based on the data indicative of the workpiece property.

12. The method of claim 1, comprising obtaining data indicative of a workpiece property, wherein the method comprises adjusting an optical path of the treatment emission of the radiation from the radiation source based on the data indicative of the workpiece property.

13. The method of claim 1, comprising obtaining data indicative of a workpiece property, wherein the method comprises adjusting a frequency modulation of the treatment emission of radiation from the radiation source based on the data indicative of the workpiece property.

14. The method of claim 1, comprising obtaining data indicative of a workpiece property, wherein the method comprises adjusting wavelength of the treatment emission of radiation from the radiation source based on the data indicative of the workpiece property.

15. The method of claim 1, comprising obtaining data indicative of a workpiece property, wherein the method comprises adjusting a focus area of the treatment emission of the radiation from the radiation source based on the data indicative of the workpiece property.

16. The method of claim 1, comprising obtaining data indicative of a workpiece property, wherein the method comprises adjusting a power modulation of the treatment emission of the radiation from the radiation source based on the data indicative of the workpiece property.

17. The method of claim 1, wherein the semiconductor workpiece is a silicon carbide boule.

18. The method of claim 1, wherein the subsurface damage region is a laser-based damage region in the semiconductor workpiece or an ion implantation damage region in the semiconductor workpiece.

19. A method for processing a semiconductor workpiece comprising:
providing a semiconductor workpiece;
inducing a subsurface damage region with a damage-inducing emission of radiation from a first radiation source;
performing a treatment process on the subsurface damage region with a treatment emission of radiation from a second radiation source; and
wherein the damage-inducing emission of radiation from the first radiation source differs from the treatment emission of radiation from the second radiation source.

20. A system for processing a semiconductor workpiece, the system comprising:
a first radiation source configured to provide a damage-inducing emission, wherein the damage-inducing emission is configured to induce a subsurface damage region in the semiconductor workpiece;
a second radiation source configured to provide a treatment emission, wherein the treatment emission is configured to perform a treatment process on the subsurface damage region of the semiconductor workpiece; and
at least one translation stage operable to impart relative motion between the subsurface damage region of the semiconductor workpiece and the radiation source.
